(19) United States
(12) Patent Application Publication
(10) Pub. No.: US 2024/0072058 A1
(43) Pub. Date: Feb. 29, 2024

(54) OUTPUT CIRCUIT

(71) Applicant: Socionext Inc., Kanagawa (JP)

(72) Inventors: Isaya SOBUE, Yokohama-shi (JP); Hidetoshi TANAKA, Yokohama-shi (JP)

(21) Appl. No.: 18/489,440

(22) Filed: Oct. 18, 2023

Related U.S. Application Data
(63) Continuation of application No. PCT/JP2022/017394, filed on Apr. 8, 2022.

(30) Foreign Application Priority Data
Apr. 22, 2021 (JP) 2021-072819

(51) Int. Cl. H01L 27/118

(52) U.S. Cl. CPC H01L 27/11807; H01L 2027/11881

(57) ABSTRACT

In a semiconductor integrated circuit device, an output circuit includes a first transistor connected between VSS and an output terminal. A first power line supplying VSS is formed in a buried interconnect layer, and above the buried interconnect layer, a second power line supplying VSS is formed in an M1 interconnect layer and a third power line connected to the second power line is formed in an M2 interconnect layer. A first output interconnect is formed in the M1 interconnect layer, and a second output interconnect connected to the first output interconnect is formed in the M2 interconnect layer.

### CROSS-REFERENCE TO RELATED APPLICATIONS

This is a continuation of International Application No. PCT/JP2022/017394 filed on Apr. 8, 2022, which claims priority to Japanese Patent Application No. 2021-072819 filed on Apr. 22, 2021. The entire disclosures of these applications are incorporated by reference herein.

### BACKGROUND

The present disclosure relates to a semiconductor integrated circuit device having buried power rails (BPRs), and more particularly, to a layout structure of an output circuit.

A semiconductor integrated circuit device has an input/output circuit for inputting/outputting signals from/to the outside through an input/output pad. An output circuit in such an input/output circuit passes a large current through it, and so full attention should be given to its layout structure.

For higher integration of a semiconductor integrated circuit device, it has been proposed to use buried power rails (BPRs) constituted by metal lines laid in a buried interconnect layer that is buried in a substrate, not power lines laid in a metal interconnect layer formed above transistors as conventionally done.

International Patent Publication No. WO2020/235082 (Patent Document 1) and International Patent Publication No. WO2020/235084 (Patent Document 2) disclose a technology using BPRs in a diode portion of an input/output circuit of a semiconductor integrated circuit device.

Neither Patent Document 1 nor 2 however discloses a concrete layout structure related to a circuit that passes a large current through it, like an output circuit of an input/output circuit.

An objective of the present disclosure is implementing an output circuit capable of passing a large current to an output terminal in a semiconductor integrated circuit device having BPRs.

### SUMMARY

According to the first mode of the present disclosure, an output circuit for outputting a signal from a semiconductor integrated circuit includes: a first transistor of a first conductivity type connected between a first power supply supplying a first power supply voltage and an output terminal; a first power line formed in a buried interconnect layer, the first power line extending in a first direction and supplying the first power supply voltage; a second power line formed in a first interconnect layer located above the buried interconnect layer, the second power line extending in the first direction and supplying the first power supply voltage; a third power line formed in a second interconnect layer located above the first interconnect layer, the third power line extending in a second direction perpendicular to the first direction and being connected to the second power line; a first output interconnect formed in the first interconnect layer, the first output interconnect extending in the first direction and being connected to the output terminal; and a second output interconnect formed in the second interconnect layer, the second output interconnect extending in the second direction and being connected to the first output interconnect.

According to the above mode, the output circuit includes the first transistor of the first conductivity type connected between the first power supply supplying the first power supply voltage and the output terminal. The power lines supplying the first power supply voltage are formed in the buried interconnect layer and the first and second interconnect layers located above the buried interconnect layer. Since this decreases the resistance value in the first power supply route, it is possible to thicken the output interconnects in the first and second interconnect layers while preventing increase in the area of the output circuit. Therefore, a large current can be passed to the output terminal.

According to the second mode of the present disclosure, an output circuit for outputting a signal from a semiconductor integrated circuit includes: a first transistor of a first conductivity type connected between a first power supply supplying a first power supply voltage and an output terminal; a first power line formed in a buried interconnect layer, the first power line extending in a first direction and supplying the first power supply voltage; a second power line formed in a first interconnect layer located above the buried interconnect layer, the second power line extending in a second direction perpendicular to the first direction and supplying the first power supply voltage; a third power line formed in a second interconnect layer located above the first interconnect layer, the third power line extending in the first direction and being connected to the second power line; a first output interconnect formed in the first interconnect layer, the first output interconnect extending in the second direction and being connected to the output terminal; and a second output interconnect formed in the second interconnect layer, the second output interconnect extending in the first direction and being connected to the first output interconnect.

According to the above mode, the output circuit includes the first transistor of the first conductivity type connected between the first power supply supplying the first power supply voltage and the output terminal. The power lines supplying the first power supply voltage are formed in the buried interconnect layer and the first and second interconnect layers located above the buried interconnect layer. Since this decreases the resistance value in the first power supply route, it is possible to thicken the output interconnect in the second interconnect layer while preventing increase in the area of the output circuit. Therefore, a large current can be passed to the output terminal.

According to the third mode of the present disclosure, an output circuit configured in a semiconductor integrated circuit device including a stack of a first semiconductor chip and a second semiconductor chip, a back face of the first semiconductor chip being opposed to a principal face of the second semiconductor chip is provided. The output circuit includes in the first semiconductor chip: a first transistor of a first conductivity type connected between a first power supply supplying a first power supply voltage and an output terminal; a first power line formed in a buried interconnect layer, the first power line extending in a first direction and supplying the first power supply voltage; a first output interconnect formed in a first interconnect layer located above the buried interconnect layer, the first output interconnect extending in the first direction and being connected to the output terminal; and a second output interconnect formed in a second interconnect layer located above the first interconnect layer, the second output interconnect extending in a second direction perpendicular to the first direction and being connected to the first output interconnect. The output circuit further includes in the second semiconductor chip: a second power line extending in the second direction and having an overlap with the second output interconnect in planar view, wherein the second power line is connected to the first power line through a via formed on the back face of the first semiconductor chip.

According to the above mode, the output circuit includes the first transistor of the first conductivity type connected between the first power supply supplying the first power supply voltage and the output terminal in the first semiconductor chip. The power lines supplying the first power supply voltage are formed in the buried interconnect layer of the first semiconductor chip and in the second semiconductor chip. With this, the resistance value in the first power supply route can be reduced even when no power line is provided in the first and second interconnect layers of the first semiconductor chip. Therefore, since the output interconnects in the first and second interconnect layers can be thickened, a large current can be passed to the output terminal. Moreover, the power line formed in the second semiconductor chip can also be thickened as it has an overlap with the output interconnect in planar view.

According to the fourth mode of the present disclosure, an output circuit configured in a semiconductor integrated circuit device including a stack of a first semiconductor chip and a second semiconductor chip, a back face of the first semiconductor chip being opposed to a principal face of the second semiconductor chip is provided. The output circuit includes in the first semiconductor chip: a first transistor of a first conductivity type connected between a first power supply supplying a first power supply voltage and an output terminal; a first power line formed in a buried interconnect layer, the first power line extending in a first direction and supplying the first power supply voltage; a first output interconnect formed in a first interconnect layer located above the buried interconnect layer, the first output interconnect extending in a second direction perpendicular to the first direction and being connected to the output terminal; and a second output interconnect formed in a second interconnect layer located above the first interconnect layer, the second output interconnect extending in the first direction and being connected to the first output interconnect. The output circuit further includes in the second semiconductor chip: a second power line extending in the first direction and having an overlap with the second output interconnect in planar view, wherein the second power line is connected to the first power line through a via formed on the back face of the first semiconductor chip.

According to the above mode, the output circuit includes the first transistor of the first conductivity type connected between the first power supply supplying the first power supply voltage and the output terminal in the first semiconductor chip. The power lines supplying the first power supply voltage are formed in the buried interconnect layer of the first semiconductor chip and in the second semiconductor chip. With this, the resistance value in the first power supply route can be reduced even when no power line is provided in the second interconnect layer of the first semiconductor chip. Therefore, since the output interconnect in the second interconnect layer can be thickened, a large current can be passed to the output terminal. Moreover, the power line formed in the second semiconductor chip can also be thickened as it has an overlap with the output interconnect in planar view.

According to the present disclosure, an output circuit capable of passing a large current to an output terminal can be implemented in a semiconductor integrated circuit device having BPRs.

### BRIEF DESCRIPTION OF THE DRAWINGS

FIG. 1 shows the entire configuration of a semiconductor integrated circuit device according to an embodiment.

FIGS. 2A-2B are simplified configuration diagrams of IO cells.

FIG. 3 is a circuit diagram of an output circuit in an embodiment.

FIG. 4 is a plan view showing a layout of an IO cell in the first embodiment.

FIG. 5 is a plan view showing some layers in FIG. 4.

FIG. 6 is a plan view showing some layers in FIG. 4.

FIGS. 7A-7C show cross-sectional structures of the layout of FIG. 4.

FIG. 8 is a plan view showing a layout of an IO cell in the first embodiment.

FIG. 9 is a circuit diagram of an output circuit in an alteration.

FIG. 10 is a plan view showing a layout of an IO cell in the alteration.

FIG. 11 is a plan view showing a layout of an IO cell in the alteration.

FIG. 12 shows the entire configuration of a semiconductor integrated circuit device according to the second embodiment.

FIG. 13 is a plan view showing a layout of an IO cell in the second embodiment.

FIG. 14 is a plan view showing some layers in FIG. 13.

FIG. 15 is a plan view showing some layers in FIG. 13.

FIG. 16 is a plan view showing some layers in FIG. 13.

FIGS. 17A-17C show cross-sectional structures of the layout of FIG. 13.

FIG. 18 is a plan view showing a layout of an IO cell in the second embodiment.

FIG. 19 is a plan view showing a layout of an IO cell in Configuration Example 1 of the third embodiment.

FIG. 20 is a plan view showing some layers in FIG. 19.

FIG. 21 is a plan view showing some layers in FIG. 19.

FIG. 22 is a plan view showing a layout of an IO cell in Configuration Example 1 of the third embodiment.

FIG. 23 is a plan view showing a layout of an IO cell in Configuration Example 2 of the third embodiment.

FIG. 24 is a plan view showing some layers in FIG. 23.

FIG. 25 is a plan view showing some layers in FIG. 23.

FIG. 26 shows an alteration of the configuration of FIG. 23.

FIG. 27 is a plan view showing a layout of an IO cell in Configuration Example 2 of the third embodiment.

FIG. 28 shows an alteration of the configuration of FIG. 27.

FIG. 29 is a plan view showing a layout of an IO cell in Configuration Example 3 of the third embodiment.

FIG. 30 is a plan view showing some layers in FIG. 29.

FIG. 31 is a plan view showing some layers in FIG. 29.

FIG. 32 is a plan view showing some layers in FIG. 29.

FIG. 33 is a plan view showing a layout of an IO cell in Configuration Example 3 of the third embodiment.

### DETAILED DESCRIPTION

Embodiments of the present disclosure will be described hereinafter with reference to the accompanying drawings. Note that, in the following description, “VSS” and “VDDIO” indicate power supplies themselves or the power supply voltages.

### First Embodiment

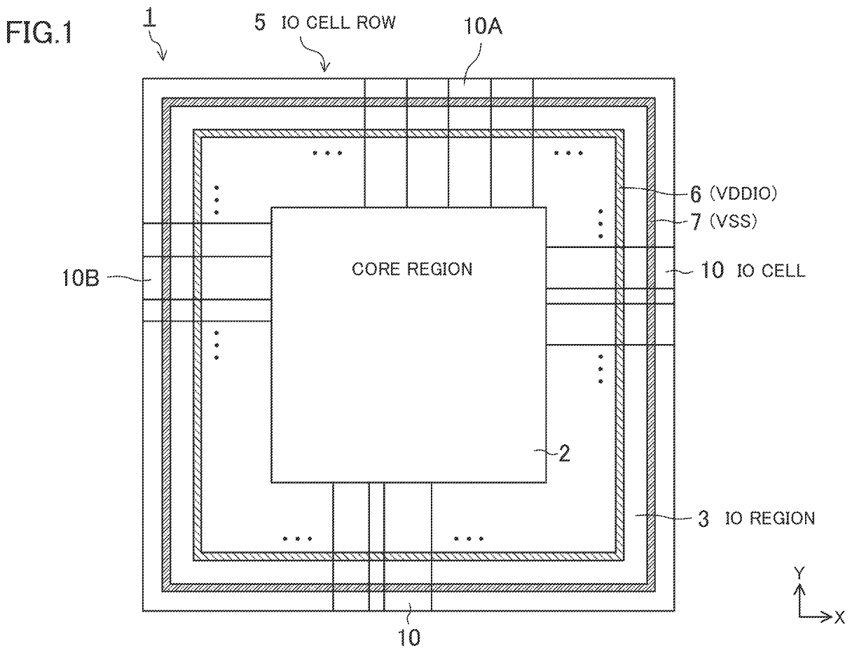

FIG. 1 is a plan view schematically showing the entire configuration of a semiconductor integrated circuit device (semiconductor chip) according to an embodiment. Note that, in FIG. 1, the horizontal direction in the figure is called the X direction and the vertical direction in the figure is called the Y direction. This also applies to the subsequent drawing. A semiconductor integrated circuit device 1 shown in FIG. 1 includes: a core region 2 in which internal core circuits are formed; and an IO region 3 provided around the core region 2, in which interface circuits (IO circuits) are formed. An IO cell row 5 is provided in the IO region 3 to surround the core region 2 in a peripheral portion of the semiconductor integrated circuit device 1. Although illustration is simplified in FIG. 1, a plurality of IO cells 10 constituting the interface circuits are arranged in line in the IO cell row 5.

The IO cells 10 include signal IO cells engaging in input, output, or input/output of signals, power IO cells for supplying a ground potential (power supply volage VSS), and power IO cells for supplying power (power supply voltage VDDIO) mainly to the IO region 3. VDDIO is 1.8 V, for example. In FIG. 1, IO cells 10A for signal input/output are placed on the upper side of the core region 2 in the figure, and IO cells 10B for signal input/output are placed on the left side of the core region 2 in the figure.

Power lines 6 and 7 extending in the direction in which the IO cells are arranged in line are provided in the IO region 3. The power lines 6 and 7 are each formed in a ring in the peripheral portion of the semiconductor integrated circuit device 1 (these power lines are also called the ring power lines). The power line 6 supplies VDDIO and the power line 7 supplies VSS. Although illustration is omitted in FIG. 1, a plurality of external connection pads are placed in the semiconductor integrated circuit device 1.

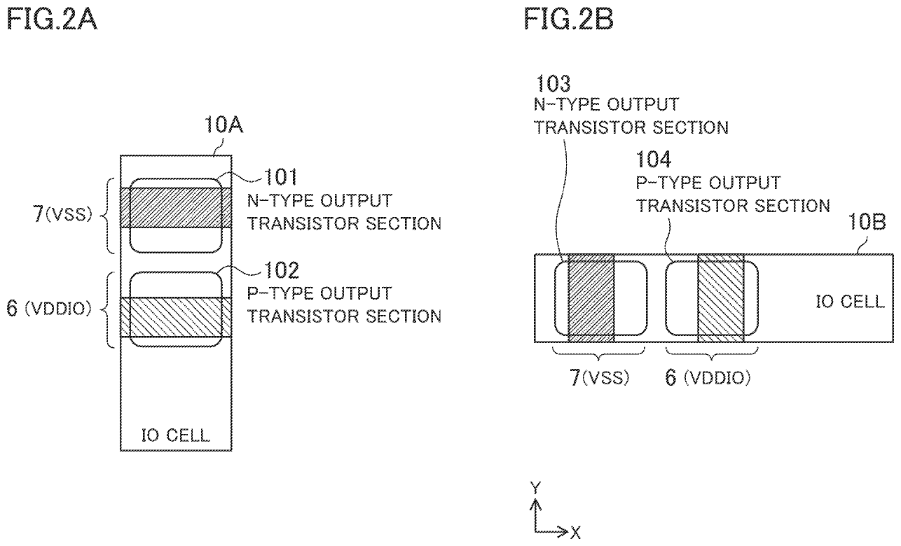

FIGS. 2A-2B are simplified configuration diagrams of the IO cells 10A and 10B. As shown in FIG. 2A, the IO cell 10A includes the power lines 6 and 7 extending in the X direction. In the IO cell 10A, an n-conductivity type (n-type) output transistor section 101 is provided under the power line 7, and a p-conductivity type (p-type) output transistor section 102 is provided under the power line 6. The n-type output transistor section 101 and the p-type output transistor section 102 are placed at positions closer to the chip outer edge in the IO cell 10A. Also, as shown in FIG. 2B, the IO cell 10B includes the power lines 6 and 7 extending in the Y direction. In the IO cell 10B, an n-type output transistor section 103 is provided under the power line 7, and a p-type output transistor section 104 is provided under the power line 6. The n-type output transistor section 103 and the p-type output transistor section 104 are placed at positions closer to the chip outer edge in the IO cell 10B.

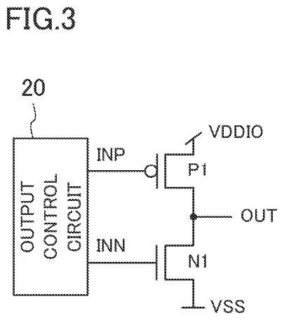

FIG. 3 is a circuit diagram of an output circuit in this embodiment. In the output circuit of FIG. 3, a p-type transistor P1 is provided between the power supply VDDIO and an output terminal that outputs an output signal OUT, and an n-type transistor N1 is provided between the power supply VSS and the output terminal. An output control circuit 20 outputs output control signals INP and INN. The transistor P1 receives the output control signal INP at its gate, and the transistor N1 receives the output control signal INN at its gate. The output signal OUT is supplied to an external connection pad. The output signal OUT becomes high (VDDIO) when the output control signals INP and INN are low, and becomes low (VSS) when the output control signals INP and INN are high.

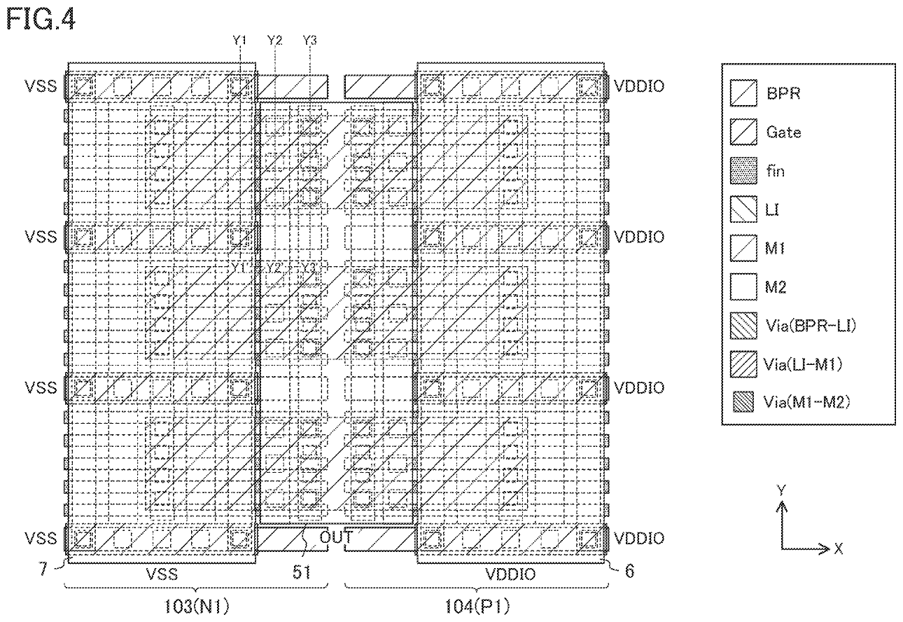

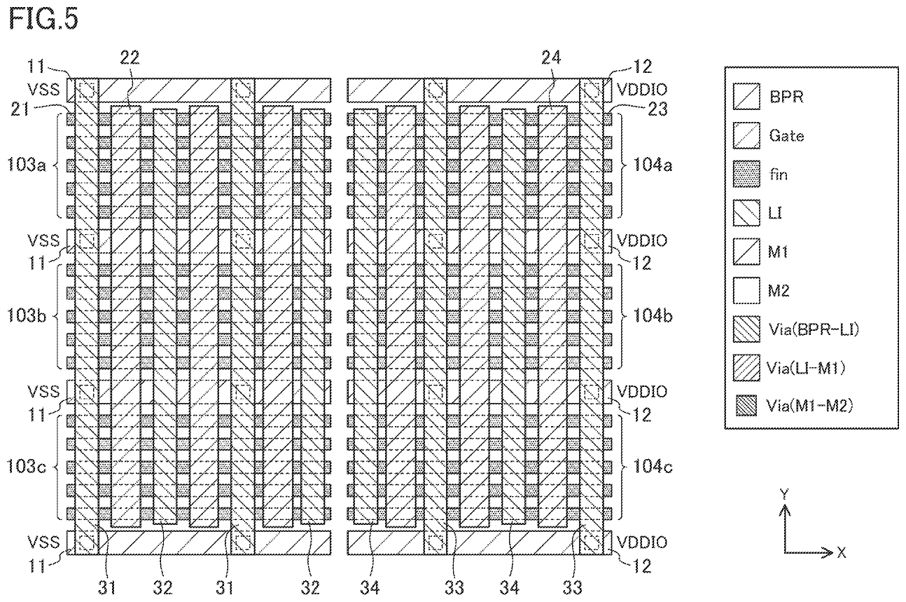

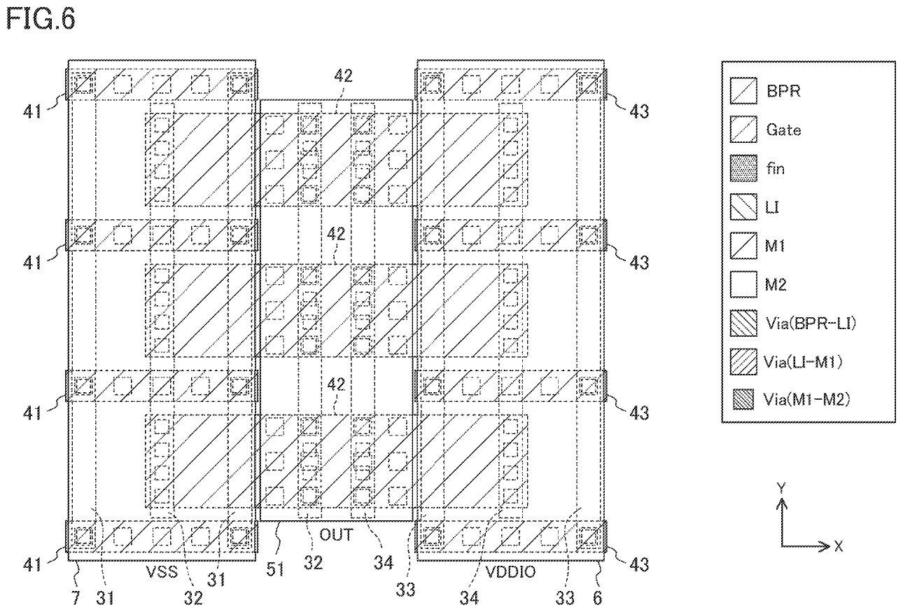

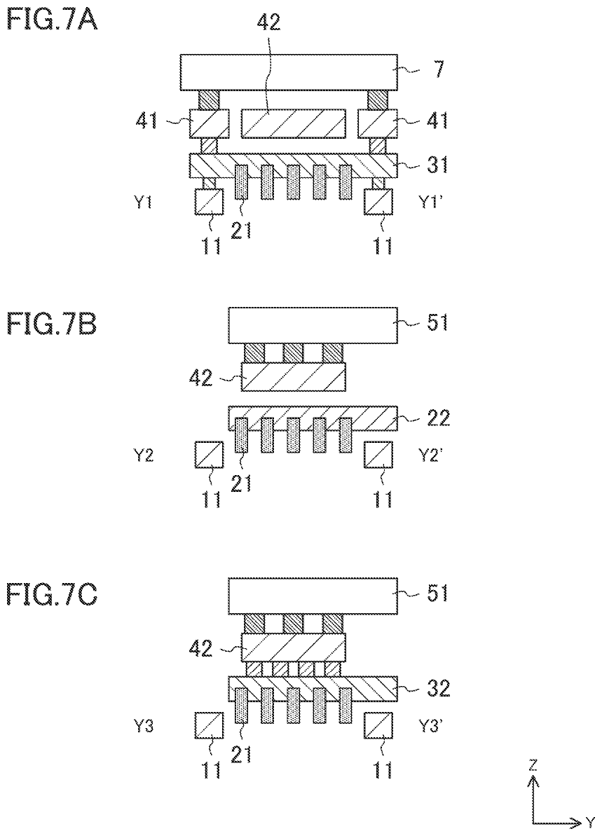

FIG. 4 is a plan view showing a layout of the output transistor sections of the IO cell 10B shown in FIG. 2B in this embodiment. FIGS. 5 and 6 are plan views showing the layout of FIG. 4 on a layer-by-layer basis, in which FIG. 5 shows a configuration of local interconnects and the lower portion below them and FIG. 6 shows a configuration of the local interconnects and the upper portion above them. FIGS. 7A-7C are cross-sectional views of the layout of FIG. 4, in which FIG. 7A shows a cross-sectional structure taken along line Y1-Y1′, FIG. 7B shows a cross-sectional structure taken along line Y2-Y2′, and FIG. 7C shows a cross-sectional structure taken along line Y3-Y3′.

In FIGS. 4 to 6, the left part of each figure corresponds to the n-type output transistor section 103 constituting the transistor N1, and the right part thereof corresponds to the p-type output transistor section 104 constituting the transistor P1. Fin FETs are formed in the n-type output transistor section 103 and the p-type output transistor section 104. Also, the power lines 6 and 7 shown in FIG. 2B are formed in an M2 interconnect layer. The power line 7 supplying VSS is provided above the n-type output transistor section 103, and the power line 6 supplying VDDIO is provided above the p-type output transistor section 104.

The n-type output transistor section 103 includes three portions 103a, 103b, and 103c each having five fins 21 extending in parallel in the X direction. Buried power rails 11 extending in the X direction are placed on the upper and lower sides of each of the portions 103a, 103b, and 103c in the figure. The buried power rails 11 supply VSS. Gate interconnects 22 extending in the Y direction are placed across the portions 103a, 103b, and 103c. Fin FETs are formed by the fins 21 and the gate interconnects 22.

Local interconnects 31 extending in the Y direction are connected in common to terminals of the fins 21 that are to be the sources of the fin FETs. The local interconnects 31 are connected to the buried power rails 11 through vias to supply VSS to the sources of the fin FETs. Local interconnects 32 extending in the Y direction are connected in common to terminals of the fins 21 that are to be the drains of the fin FETs.

The local interconnects 31 are connected to M1 interconnects 41 extending in the X direction through vias. Here, the M1 interconnects 41 are placed to overlap the buried power rails 11 in planar view. The M1 interconnects 41 are connected to the power line 7 formed in the M2 interconnect layer through vias.

The local interconnects 32 are connected to M1 interconnects 42 extending in the X direction through vias. The M1 interconnects 42 are connected to an M2 interconnect 51 through vias. The M1 interconnects 42 and the M2 interconnect 51 correspond to output interconnects. The M2 interconnect 51 is connected to an upper-layer pad electrode not shown.

The configuration of the p-type output transistor section 104 is similar to that of the n-type output transistor section 103. The p-type output transistor section 104 includes three portions 104a, 104b, and 104c each having five fins 23 extending in parallel in the X direction. Buried power rails 12 extending in the X direction are placed on the upper and lower sides of each of the portions 104a, 104b, and 104c in the figure. The buried power rails 12 supply VDDIO. Gate interconnects 24 extending in the Y direction are placed across the portions 104a, 104b, and 104c. Fin FETs are formed by the fins 23 and the gate interconnects 24.

Local interconnects 33 extending in the Y direction are connected in common to terminals of the fins 23 that are to be the sources of the fin FETs. The local interconnects 33 are connected to the buried power rails 12 through vias to supply VDDIO to the sources of the fin FETs. Local interconnects 34 extending in the Y direction are connected in common to terminals of the fins 23 that are to be the drains of the fin FETs.

The local interconnects 33 are connected to M1 interconnects 43 extending in the X direction through vias. Here, the M1 interconnects 43 are placed to overlap the buried power rails 12 in planar view. The M1 interconnects 43 are connected to the power line 6 formed in the M2 interconnect layer through vias.

Like the local interconnects 32, the local interconnects 34 are connected to the M1 interconnects 42 extending in the X direction through vias.

According to the configuration described above, as the power lines supplying VSS, the buried power rails 11 are formed in the buried interconnect layer, the power lines 41 are formed in the M1 interconnect layer, and the power line 7 is formed in the M2 interconnect layer. Since this decreases the resistance value in the VSS supply route, the power lines 7 and 41 can be thinned. Also, as the power lines supplying VDDIO, the buried power rails 12 are formed in the buried interconnect layer, the power lines 43 are formed in the M1 interconnect layer, and the power line 6 is formed in the M2 interconnect layer. Since this decreases the resistance value in the VDDIO supply route, the power lines 6 and 43 can be thinned. It is therefore possible to thicken the output interconnects 42 in the M1 interconnect layer and the output interconnect 51 in the M2 interconnect layer while preventing increase in the area of the output circuit. A large current can therefore be passed to the output terminal.

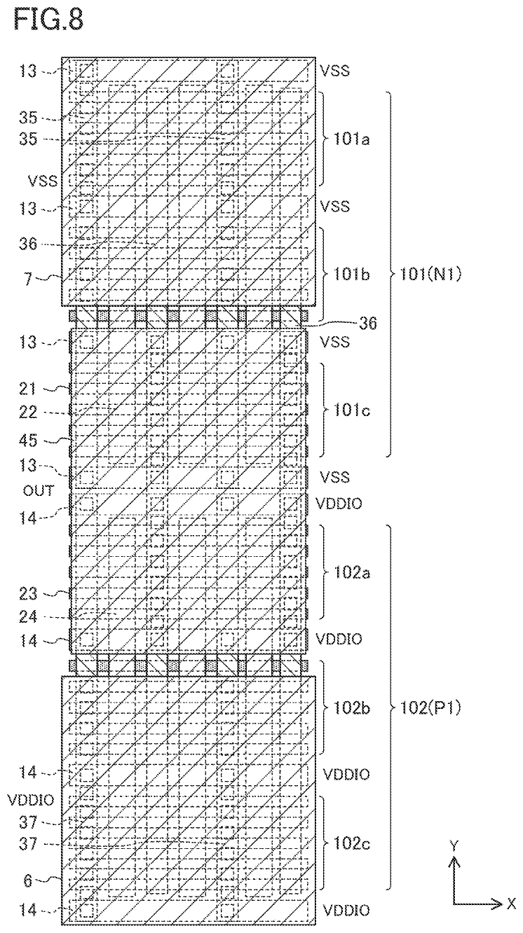

FIG. 8 is a plan view showing a layout of the output transistor sections of the IO cell 10A shown in FIG. 2A. Note that the cross-sectional structure can be easily guessed by analogy from FIGS. 7A-7C, and therefore illustration is omitted here.

In FIG. 8, the upper part of the figure corresponds to the n-type output transistor section 101 constituting the transistor N1, and the lower part thereof corresponds to the p-type output transistor section 102 constituting the transistor P1. Fin FETs are formed in the n-type output transistor section 101 and the p-type output transistor section 102. Also, the power lines 6 and 7 shown in FIG. 2A are formed in the M1 interconnect layer. The power line 7 supplying VSS is provided above the n-type output transistor section 101, and the power line 6 supplying VDDIO is provided above the p-type output transistor section 102.

The n-type output transistor section 101 includes three portions 101a, 101b, and 101c each having five fins 21 extending in parallel in the X direction. Buried power rails 13 extending in the X direction are placed on the upper and lower sides of each of the portions 101a, 101b, and 101c in the figure. The buried power rails 13 supply VSS. Gate interconnects 22 extending in the Y direction are placed across the portions 101a, 101b, and 101c. Fin FETs are formed by the fins 21 and the gate interconnects 22.

Local interconnects 35 extending in the Y direction are connected in common to terminals of the fins 21 that are to be the sources of the fin FETs. The local interconnects 35 are connected to the buried power rails 13 through vias to supply VSS to the sources of the fin FETs. The local interconnects 35 correspond to power lines, and are connected to the power line 7 formed in the M1 interconnect layer through vias.

The p-type output transistor section 102 includes three portions 102a, 102b, and 102c each having five fins 23 extending in parallel in the X direction. Buried power rails 14 extending in the X direction are placed on the upper and lower sides of each of the portions 102a, 102b, and 102c in the figure. The buried power rails 14 supply VDDIO. Gate interconnects 24 extending in the Y direction are placed across the portions 102a, 102b, and 102c. Fin FETs are formed by the fins 23 and the gate interconnects 24.

Local interconnects 37 extending in the Y direction are connected in common to terminals of the fins 23 that are to be the sources of the fin FETs. The local interconnects 37 are connected to the buried power rails 14 through vias to supply VDDIO to the sources of the fin FETs. The local interconnects 37 correspond to power lines, and are connected to the power line 6 formed in the M1 interconnect layer through vias.

Local interconnects 36 extending in the Y direction are connected in common to terminals of the fins 21 that are to be the drains of the fin FETs in the n-type output transistor section 101 and to terminals of the fins 23 that are to be the drains of the fin FETs in the p-type output transistor section 102. The local interconnects 36 are connected to an M1 interconnect 45 through vias. The local interconnects 36 and the M1 interconnect 45 correspond to output interconnects. The M1 interconnect 45 is connected to an upper-layer pad electrode not shown.

According to the configuration described above, as the power lines supplying VSS, the buried power rails 13 are formed in the buried interconnect layer, the local interconnects 35 are formed, and the power line 7 is formed in the M1 interconnect layer. Since this decreases the resistance value in the VSS supply route, the power line 7 can be thinned. Also, as the power lines supplying VDDIO, the buried power rails 14 are formed in the buried interconnect layer, the local interconnects 37 are formed, and the power line 6 is formed in the M1 interconnect layer. Since this decreases the resistance value in the VDDIO supply route, the power line 6 can be thinned. It is therefore possible to thicken the output interconnect 45 in the M1 interconnect layer while preventing increase in the area of the output circuit. A large current can therefore be passed to the output terminal.

In addition, the buried power rail 13 supplying VSS and the buried power rail 14 supplying VDDIO are formed between the transistor N1 and the transistor P1 in planar view. Since buried power rails are formed by burying metal lines in grooves formed on the substrate, wells in the substrate, STIs, and the like, they have an advantage of reducing propagation of noise through the substrate and the like. Therefore, by providing buried power rails between the transistors N1 and P1, latch-up resistance can be improved.

<Alteration>

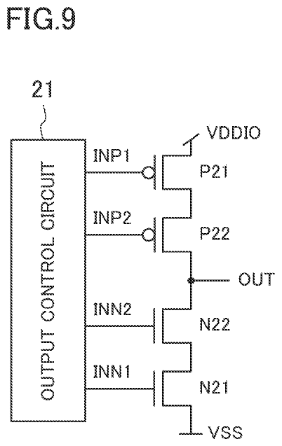

FIG. 9 is a circuit diagram of an output circuit in an alteration. In the output circuit of FIG. 9, p-type transistors P21 and P22 are provided in series between the power supply VDDIO and an output signal line, and n-type transistors N21 and N22 are provided in series between the power supply VSS and the output signal line. An output control circuit 21 outputs output control signals INP1, INP2, INN1, and INN2. The transistor P21 receives the output control signal INP1 at its gate, and the transistor P22 receives the output control signal INP2 at its gate. The transistor N21 receives the output control signal INN1 at its gate, and the transistor N22 receives the output control signal INN2 at its gate. The output signal OUT is supplied to an external connection pad. The output signal OUT becomes high (VDDIO) when the output control signals INP1, INP2, INN1, and INN2 are low, and becomes low (VSS) when the output control signals INP1, INP2, INN1, and INN2 are high. Note that one of the output control signals INP1 and INP2 may be at a fixed potential (VSS) and one of the output control signals INN1 and INN2 may be at a fixed potential (VDDIO).

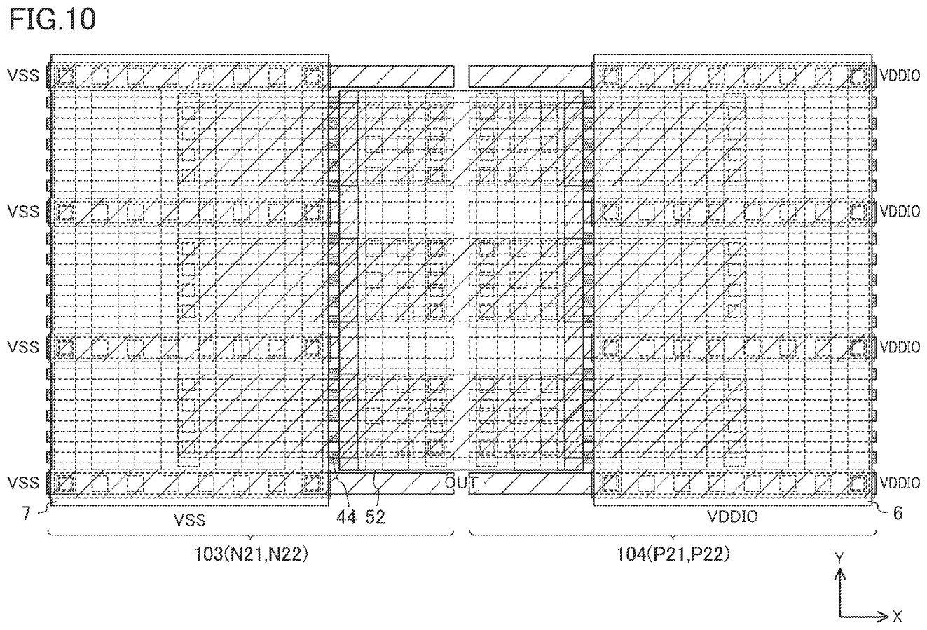

FIG. 10 is a plan view showing a layout of the output transistor sections of the IO cell 10B shown in FIG. 2B in this alteration. In FIG. 10, the left part of the figure corresponds to the n-type output transistor section 103 constituting the transistors N21 and N22, and the right part thereof corresponds to the p-type output transistor section 104 constituting the transistors P21 and P22. Fin FETs are formed in the n-type output transistor section 103 and the p-type output transistor section 104. Also, the power lines 6 and 7 shown in FIG. 2B are formed in an M2 interconnect layer. The power line 7 supplying VSS is provided above the n-type output transistor section 103, and the power line 6 supplying VDDIO is provided above the p-type output transistor section 104.

In the layout of FIG. 10, in comparison with the layout of FIG. 4, the fins are longer because transistors are in two-stage serial connection, and two gate interconnects are placed between adjacent local interconnects. The basic configuration is however similar to the one described above in this embodiment, and therefore detailed description thereof is omitted here. M1 interconnects 44 are connected to an M2 interconnect 52, and the M2 interconnect 52 is connected to an upper-layer pad electrode not shown.

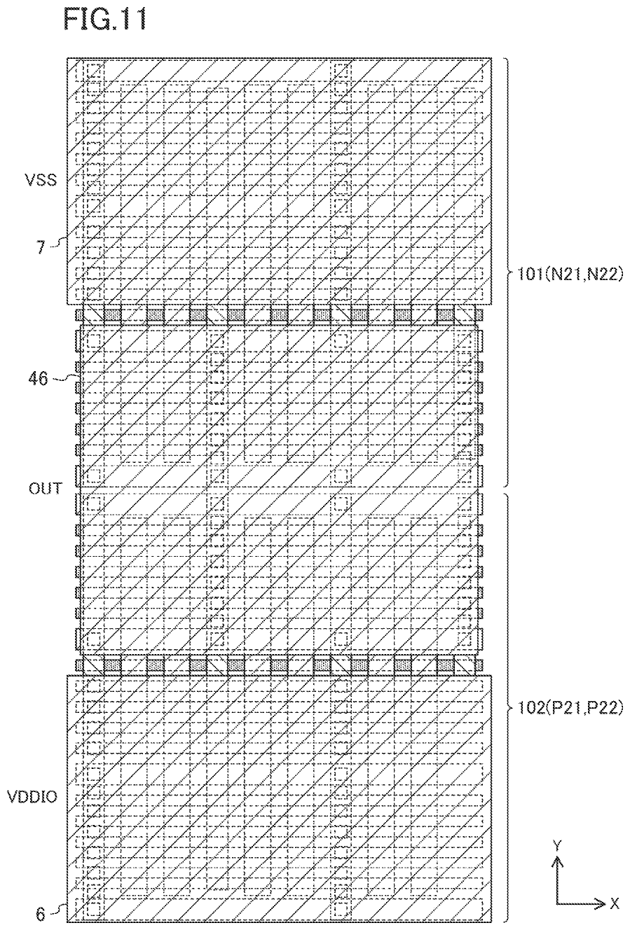

FIG. 11 is a plan view showing a layout of the output transistor sections of the IO cell 10A shown in FIG. 2A in this alteration. In FIG. 11, the upper part of the figure corresponds to the n-type output transistor section 101 constituting the transistors N21 and N22, and the lower part thereof corresponds to the p-type output transistor section 102 constituting the transistors P21 and P22. Fin FETs are formed in the n-type output transistor section 101 and the p-type output transistor section 102. Also, the power lines 6 and 7 shown in FIG. 2A are formed in an M1 interconnect layer. The power line 7 supplying VSS is provided above the n-type output transistor section 101, and the power line 6 supplying VDDIO is provided above the p-type output transistor section 102.

In the layout of FIG. 11, in comparison with the layout of FIG. 8, the fins are longer because transistors are in two-stage serial connection, and two gate interconnects are placed between adjacent local interconnects. The basic configuration is however similar to that described above in this embodiment, and therefore detailed description thereof is omitted here. An M1 interconnect 46 is connected to an upper-layer pad electrode not shown.

In this alteration, also, advantages similar to those described above in this embodiment are obtained. That is, in the layout of FIG. 10, it is possible to thicken the output interconnects 44 in the M1 interconnect layer and the output interconnect 52 in the M2 interconnect layer while preventing increase in the area of the output circuit. A large current can therefore be passed to the output terminal. In the layout of FIG. 11, it is possible to thicken the output interconnect 46 in the M1 interconnect layer while preventing increase in the area of the output circuit. A large current can therefore be passed to the output terminal.

In addition, a buried power rail supplying VSS and a buried power rail supplying VDDIO are formed between the transistors N21, N22 and the transistors P21, P22 in planar view. Since buried power rails are formed by burying metal lines in grooves provided on the substrate, wells in the substrate, STIs, and the like, they have an advantage of reducing propagation of noise through the substrate and the like. Therefore, by providing buried power rails between the transistors N21, N22 and the transistors P21, P22, latch-up resistance can be improved.

### Second Embodiment

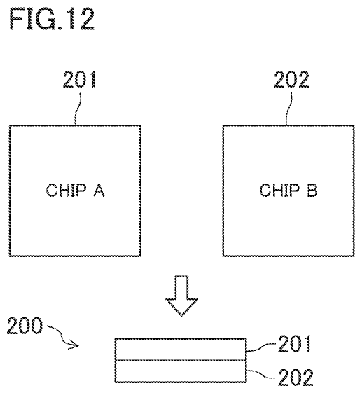

FIG. 12 is a view showing the entire configuration of a semiconductor integrated circuit device according to the second embodiment. As shown in FIG. 12, a semiconductor integrated circuit device 200 is constituted by a stack of a first semiconductor chip 201 (chip A) and a second semiconductor chip 202 (chip B). In the stack, the back face of the first semiconductor chip 201 and the principal face of the second semiconductor chip 202 are opposed to each other. In the first semiconductor chip 201, circuits including transistors constituting an output buffer are formed, and also buried power rails are formed. The second semiconductor chip 202 includes power lines to be connected to the buried power rails formed in the first semiconductor chip 201. The buried power rails formed in the first semiconductor chip 201 and the power lines formed in the first semiconductor chip 202 are mutually connected by way of through silicon vias (TSVs).

The plan view of the semiconductor integrated circuit device 200 shown in FIG. 12 is similar to that of FIG. 1. That is, the first semiconductor chip 201 includes: a core region 2 in which internal core circuits are formed; and an IO region 3 provided around the core region 2, in which interface circuits (IO circuits) are formed. An IO cell row 5 is provided in the IO region 3 to surround the core region 2 in a peripheral portion of the semiconductor integrated circuit device 200. A plurality of IO cells 10 constituting the interface circuits are arranged in line in the IO cell row 5.

In this embodiment, the power lines 6 and 7 extending in a direction in which the IO cells 10 are arranged are formed in the second semiconductor chip 202.

In this embodiment, the simplified configurations of the IO cells 10A and 10B are similar to those of FIGS. 2A and 2B, and the circuit diagram of the output circuit is similar to that of FIG. 3.

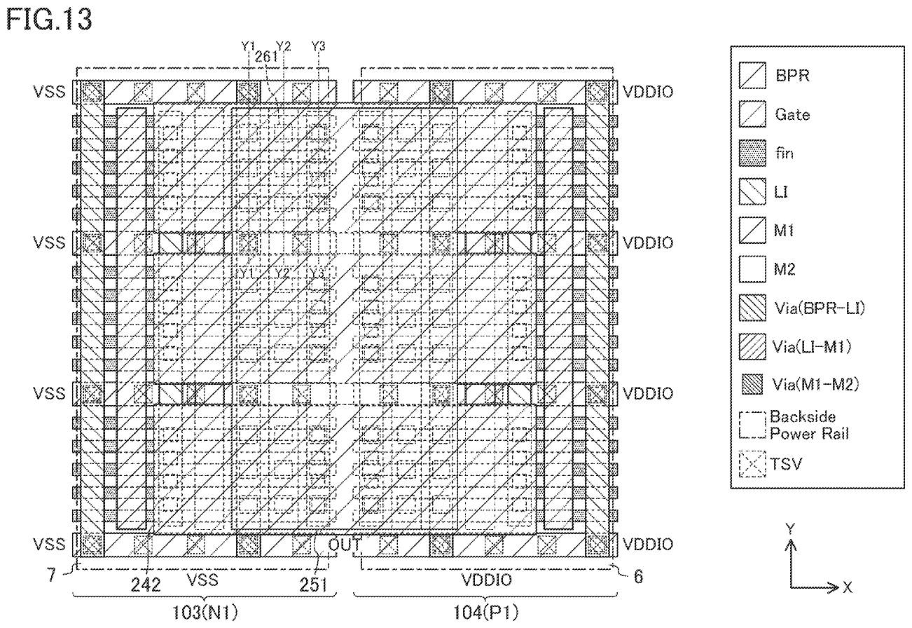

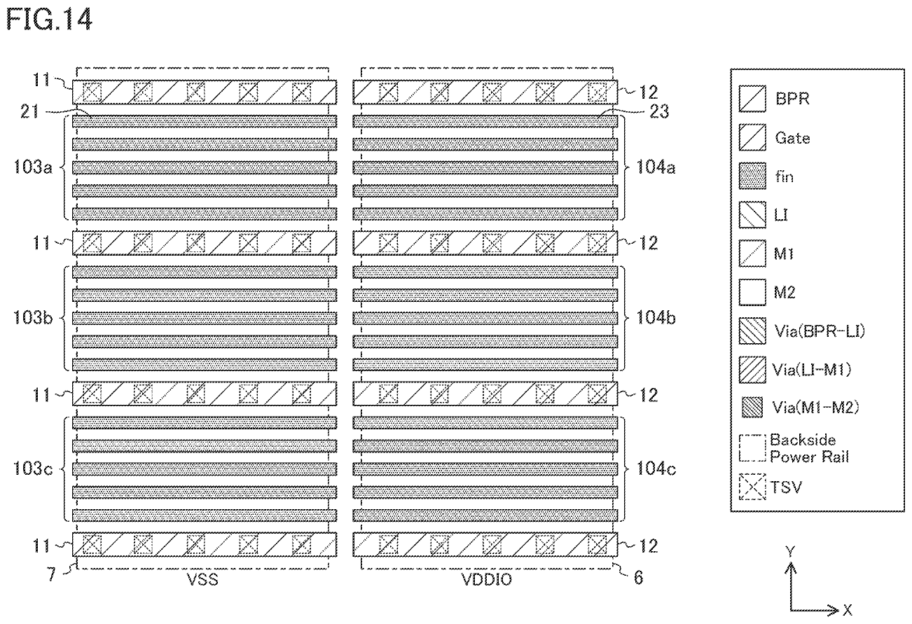

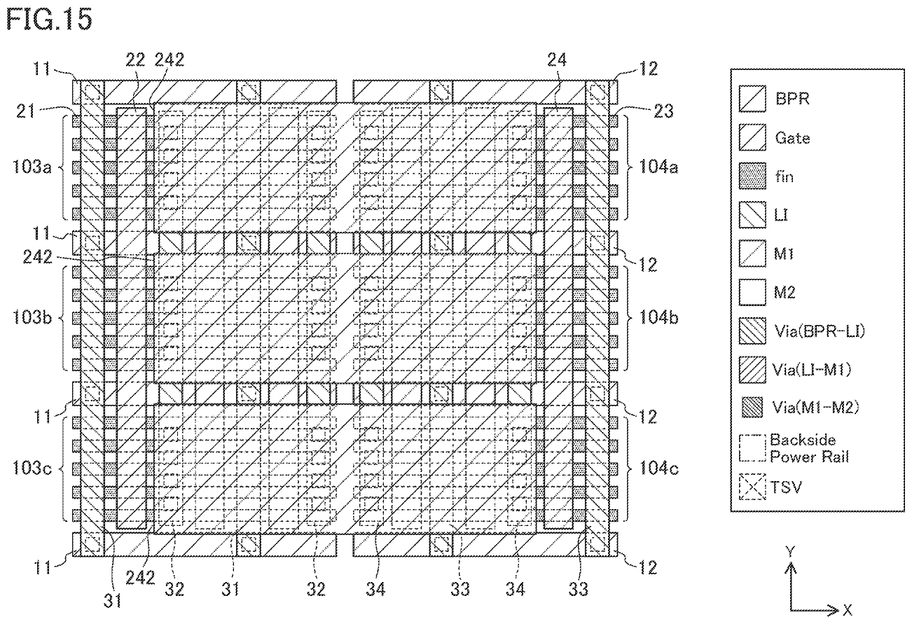

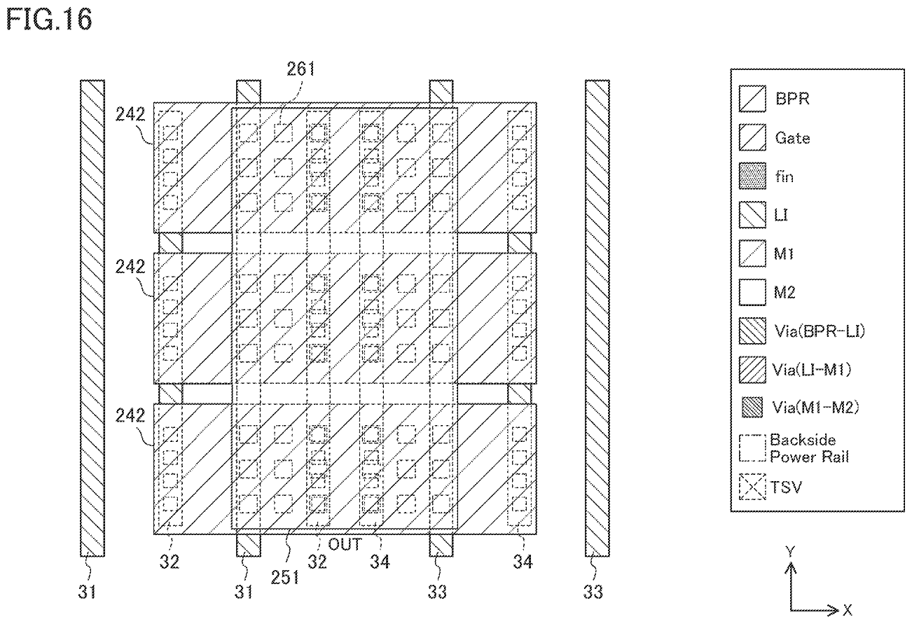

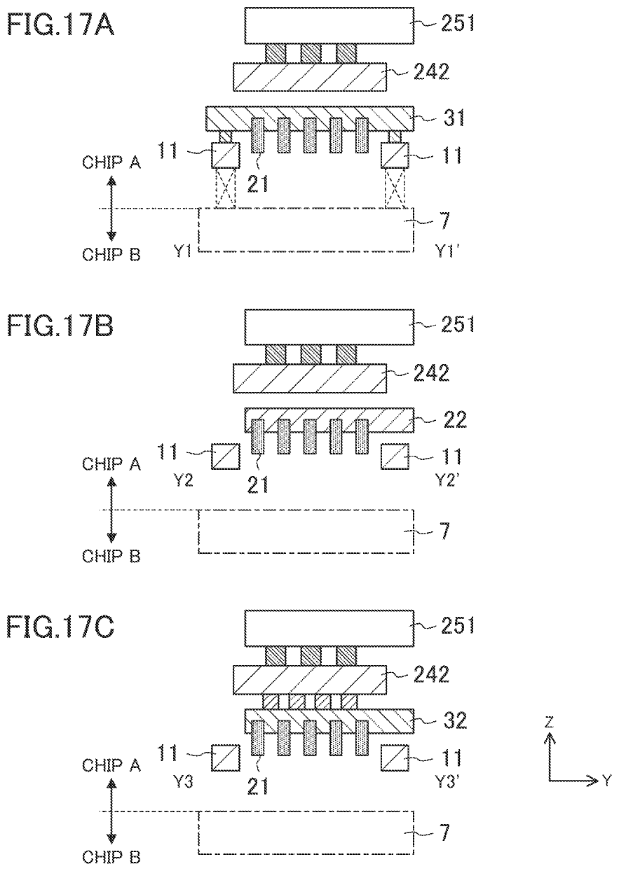

FIG. 13 is a plan view showing a layout of the output transistor sections of the IO cell 10B shown in FIG. 2B in this embodiment. The layout of FIG. 13 corresponds to the circuit diagram of FIG. 3. FIGS. 14 to 16 are plan views showing the layout of FIG. 13 on a layer-by-layer basis, in which FIG. 14 shows a configuration of power lines in the second semiconductor chip 202 and buried power rails and fins in the first semiconductor chip 201, FIG. 15 shows a configuration of M1 interconnects and the lower portion below them in the first semiconductor chip 201, and FIG. 16 shows a configuration of local interconnects and the upper portion above them in the first semiconductor chip 201. FIGS. 17A-17C are cross-sectional views of the layout of FIG. 13, in which FIG. 17A shows a cross-sectional structure taken along line Y1-Y1′, FIG. 17B shows a cross-sectional structure taken along line Y2-Y2′, and FIG. 17C shows a cross-sectional structure taken along line Y3-Y3′.

In FIGS. 13 to 16, the left part of each figure corresponds to the n-type output transistor section 103 constituting the transistor N1, and the right part thereof corresponds to the p-type output transistor section 104 constituting the transistor P1. Fin FETs are formed in the n-type output transistor section 103 and the p-type output transistor section 104. Also, the power lines 6 and 7 shown in FIG. 2B are formed in the second semiconductor chip 202. The power line 7 supplying VSS is provided to overlap the n-type output transistor section 103 in planar view, and the power line 6 supplying VDDIO is provided to overlap the p-type output transistor section 104 in planar view.

The n-type output transistor section 103 includes three portions 103a, 103b, and 103c each having five fins 21 extending in parallel in the X direction. Buried power rails 11 extending in the X direction are formed on the upper and lower sides of each of the portions 103a, 103b, and 103c in the figure. The buried power rails 11 supply VSS. The buried power rails 11 are connected to the power line 7 in the second semiconductor chip 202 through TSVs.

Gate interconnects 22 extending in the Y direction are placed across the portions 103a, 103b, and 103c. Fin FETs are formed by the fins 21 and the gate interconnects 22. Local interconnects 31 extending in the Y direction are connected in common to terminals of the fins 21 that are to be the sources of the fin FETs. The local interconnects 31 are connected to the buried power rails 11 through vias to supply VSS to the sources of the fin FETs. Local interconnects 32 extending in the Y direction are connected in common to terminals of the fins 21 that are to be the drains of the fin FETs.

The local interconnects 32 are connected to M1 interconnects 242 extending in the X direction through vias. The M1 interconnects 242 are connected to an M2 interconnect 251 through vias 261. The M1 interconnects 242 and the M2 interconnect 251 correspond to output interconnects. The M2 interconnect 251 is connected to an upper-layer pad electrode not shown.

The p-type output transistor section 104 includes three portions 104a, 104b, and 104c each having five fins 23 extending in parallel in the X direction. Buried power rails 12 extending in the X direction are formed on the upper and lower sides of each of the portions 104a, 104b, and 104c in the figure. The buried power rails 12 supply VDDIO. The buried power rails 12 are connected to the power line 6 in the second semiconductor chip 202 through TSVs.

Gate interconnects 24 extending in the Y direction are placed across the portions 104a, 104b, and 104c. Fin FETs are formed by the fins 23 and the gate interconnects 24. Local interconnects 33 extending in the Y direction are connected in common to terminals of the fins 23 that are to be the sources of the fin FETs. The local interconnects 33 are connected to the buried power rails 12 through vias to supply VDDIO to the sources of the fin FETs. Local interconnects 34 extending in the Y direction are connected in common to terminals of the fins 23 that are to be the drains of the fin FETs.

The local interconnects 34 are connected to the M1 interconnects 242 extending in the X direction through vias.

The power lines 6 and 7 in the second semiconductor chip 202 have overlaps with the M2 interconnect 251 in the first semiconductor chip 201 in planar view. Also, the positions of the vias 261 for connecting the M1 interconnects 242 and the M2 interconnect 251 overlap the power lines 6 and 7 in the second semiconductor chip 202 in planar view.

According to the configuration described above, as the power lines supplying VSS, provided are the buried power rails 11 formed in the buried interconnect layer of the first semiconductor chip 201 and the power line 7 formed in the second semiconductor chip 202. With this, the resistance value in the VSS supply route can be reduced even when no power line is provided in the M1 interconnect layer of the first semiconductor chip 201. Also, as the power lines supplying VDDIO, provided are the buried power rails 12 formed in the buried interconnect layer of the first semiconductor chip 201 and the power line 6 formed in the second semiconductor chip 202. With this, the resistance value in the VDDIO supply route can be reduced even when no power line is provided in the M1 interconnect layer of the first semiconductor chip 201. It is therefore possible to thicken the output interconnects 242 in the M1 interconnect layer and the output interconnect 251 in the M2 interconnect layer in the first semiconductor chip 201, and also increase the number of vias 261 for connecting these interconnects. A large current can therefore be passed to the output terminal. Moreover, the power lines 6 and 7 formed in the second semiconductor chip 202 can also be thickened as they have overlaps with the output interconnect 251 in planar view.

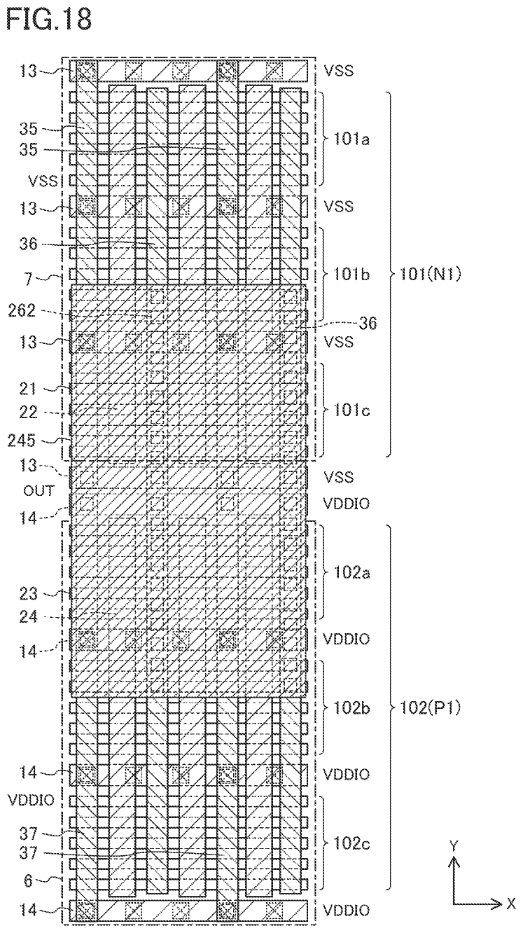

FIG. 18 is a plan view showing a layout of the output transistor sections of the IO cell 10A shown in FIG. 2A in this embodiment. Note that the cross-sectional structure can be easily guessed by analogy from FIGS. 17A-17C, and therefore illustration is omitted here.

In FIG. 18, the upper part of the figure corresponds to the n-type output transistor section 101 constituting the transistor N1, and the lower part thereof corresponds to the p-type output transistor section 102 constituting the transistor P1. Fin FETs are formed in the n-type output transistor section 101 and the p-type output transistor section 102. Also, the power lines 6 and 7 shown in FIG. 2A are formed in the second semiconductor chip 202. The power line 7 supplying VSS is provided to overlap the n-type output transistor section 101 in planar view, and the power line 6 supplying VDDIO is provided to overlap the p-type output transistor section 102 in planar view.

The n-type output transistor section 101 includes three portions 101a, 101b, and 101c each having five fins 21 extending in parallel in the X direction. Buried power rails 13 extending in the X direction are placed on the upper and lower sides of each of the portions 101a, 101b, and 101c in the figure. The buried power rails 13 supply VSS. The buried power rails 13 are connected to the power line 7 in the second semiconductor chip 202 through TSVs.

Gate interconnects 22 extending in the Y direction are placed across the portions 101a, 101b, and 101c. Fin FETs are formed by the fins 21 and the gate interconnects 22. Local interconnects 35 extending in the Y direction are connected in common to terminals of the fins 21 that are to be the sources of the fin FETs. The local interconnects 35 are connected to the buried power rails 13 through vias to supply VSS to the sources of the fin FETs.

The p-type output transistor section 102 includes three portions 102a, 102b, and 102c each having five fins 23 extending in parallel in the X direction. Buried power rails 14 extending in the X direction are formed on the upper and lower sides of each of the portions 102a, 102b, and 102c in the figure. The buried power rails 14 supply VDDIO. The buried power rails 14 are connected to the power line 6 in the second semiconductor chip 202 through TSVs.

Gate interconnects 24 extending in the Y direction are placed across the portions 102a, 102b, and 102c. Fin FETs are formed by the fins 23 and the gate interconnects 24. Local interconnects 37 extending in the Y direction are connected in common to terminals of the fins 23 that are to be the sources of the fin FETs. The local interconnects 37 are connected to the buried power rails 14 through vias to supply VDDIO to the sources of the fin FETs.

Local interconnects 36 extending in the Y direction are connected in common to terminals of the fins 21 that are to be the drains of the fin FETs in the n-type output transistor section 101 and to terminals of the fins 23 that are to be the drains of the fin FETs in the p-type output transistor section 102. The local interconnects 36 are connected to an M1 interconnect 245 through vias 262. The local interconnects 36 and the M1 interconnect 245 correspond to output interconnects. The M1 interconnect 245 is connected to an upper-layer pad electrode not shown.

The power lines 6 and 7 in the second semiconductor chip 202 have overlaps with the M1 interconnect 245 in the first semiconductor chip 201 in planar view. Also, the positions of the vias 262 for connecting the local interconnects 36 and the M1 interconnect 245 overlap the power lines 6 and 7 in the second semiconductor chip 202 in planar view.

According to the configuration described above, as the power lines supplying VSS, provided are the buried power rails 13 formed in the buried interconnect layer of the first semiconductor chip 201 and the power line 7 formed in the second semiconductor chip 202. With this, the resistance value in the VSS supply route can be reduced even when no power line is provided in the M1 interconnect layer of the first semiconductor chip 201. Also, as the power lines supplying VDDIO, provided are the buried power rails 14 formed in the buried interconnect layer of the first semiconductor chip 201 and the power line 6 formed in the second semiconductor chip 202. With this, the resistance value in the VDDIO supply route can be reduced even when no power line is provided in the M1 interconnect layer of the first semiconductor chip 201. It is therefore possible to thicken the output interconnect 245 in the first semiconductor chip 201, and also increase the number of vias 262 for connection with the local interconnects 36. A large current can therefore be passed to the output terminal. Moreover, the power lines 6 and 7 formed in the second semiconductor chip 202 can also be thickened as they have overlaps with the output interconnect 245 in planar view.

In this embodiment, the power lines 6 and 7 in the second semiconductor chip 202 may be formed in a single layer or in a plurality of layers. Also, the direction of extension of the power lines is not limited to the one illustrated here. For example, power lines in one layer may be made to extend in a direction perpendicular to the direction in which power lines in an adjacent layer extend, forming a mesh shape. With this, the power supply can be further strengthened.

In this embodiment, while both the VSS line and the VDDIO line are formed in the second semiconductor chip 202, only either the VSS line or the VDDIO line may be formed in the second semiconductor chip 202.

As in the alteration of the first embodiment, this embodiment can also be configured to adopt output transistors in two-stage serial connection.

### Third Embodiment

In the embodiments described above, the BPRs, i.e., the power rails formed in the buried interconnect layer extend in the X direction. In the third embodiment, examples in which BPRs extend in the Y direction will be described as configurations corresponding to the above embodiments.

### Configuration Example 1

Configuration Example 1 corresponds to the first embodiment. The circuit configuration of the output circuit is as shown in the circuit diagram of FIG. 3.

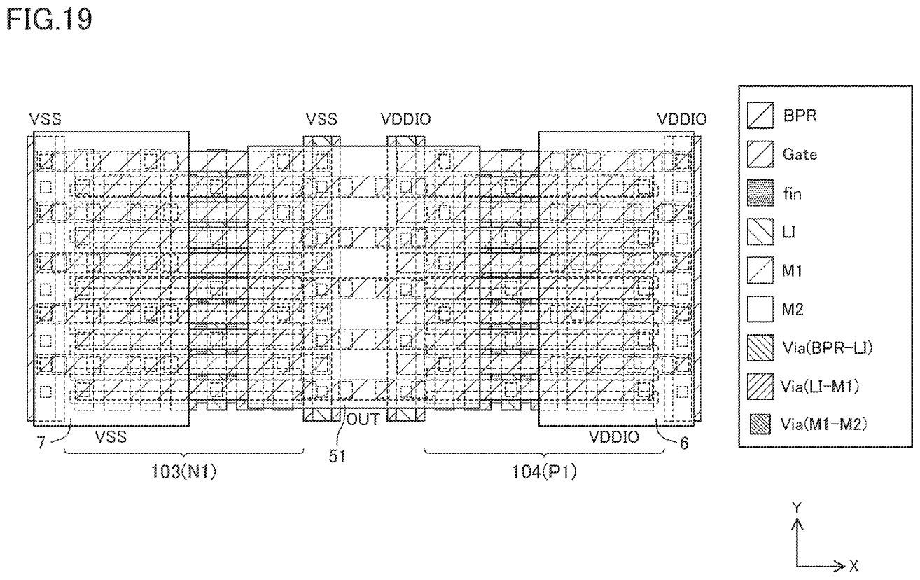

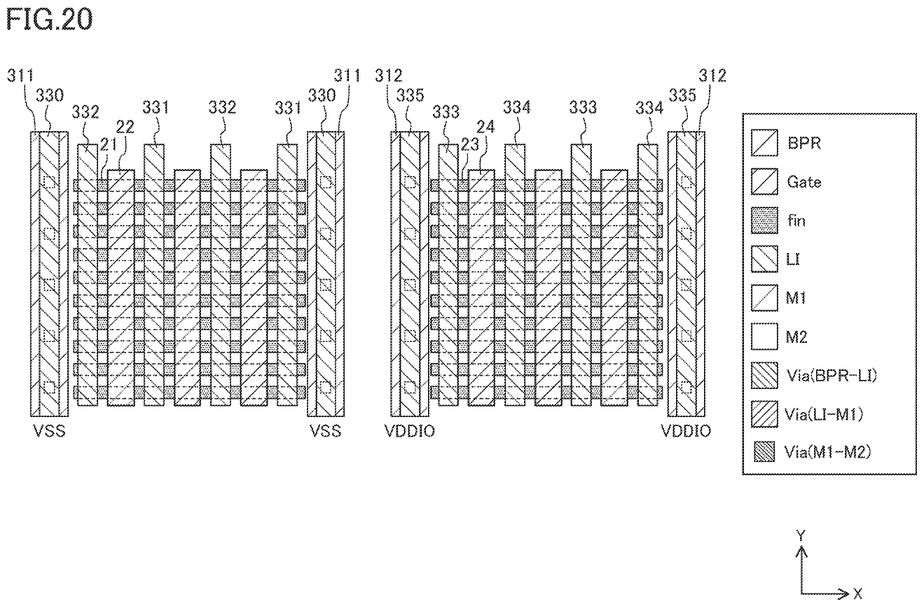

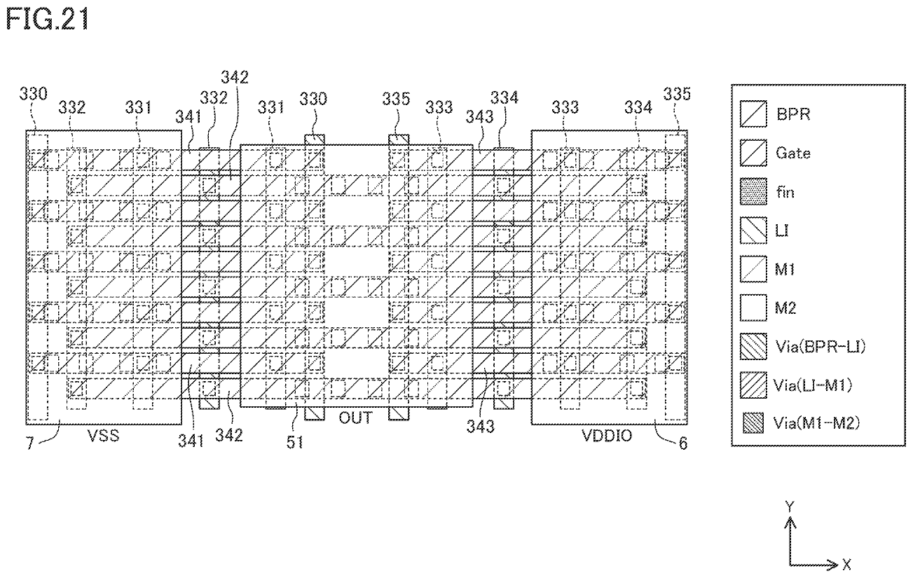

FIG. 19 is a plan view showing a layout of the output transistor sections of the IO cell 10B shown in FIG. 2B in this configuration example. FIGS. 20 and 21 are plan views showing the layout of FIG. 19 on a layer-by-layer basis, in which FIG. 20 shows a configuration of local interconnects and the lower portion below them and FIG. 21 shows a configuration of the local interconnects and the upper portion above them. FIGS. 19 to 21 are views corresponding to FIGS. 4 to 6 shown in the first embodiment, and therefore description may be omitted here for configurations that can be easily guessed by analogy from the description in the first embodiment.

In FIGS. 19 to 21, the left part of each figure corresponds to the n-type output transistor section 103 constituting the transistor N1, and the right part thereof corresponds to the p-type output transistor section 104 constituting the transistor P1. Fin FETs are formed in the n-type output transistor section 103 and the p-type output transistor section 104. Also, the power lines 6 and 7 shown in FIG. 2B are formed in an M2 interconnect layer. The power line 7 supplying VSS is provided above the n-type output transistor section 103, and the power line 6 supplying VDDIO is provided above the p-type output transistor section 104. Also, an output interconnect 51 is formed in the M2 interconnect layer. The M2 interconnect 51 is connected to an upper-layer pad electrode not shown.

The n-type output transistor section 103 includes ten fins 21 extending in parallel in the X direction. Buried power rails 311 extending in the Y direction are placed on the left and right sides of the fins 21 in the figure. The buried power rails 311 supply VSS. Gate interconnects 22 extending in the Y direction are placed across the ten fins 21. Fin FETs are formed by the fins 21 and the gate interconnects 22.

Local interconnects 330 extending in the Y direction are formed above the buried power rails 311 to overlap the buried power rails 311 in planar view. The local interconnects 330 are connected to the underlying buried power rails 311 through vias.

Local interconnects 331 extending in the Y direction are connected in common to terminals of the fins 21 that are to be the sources of the fin FETs. The local interconnects 331 are connected to the local interconnects 330 through five M1 interconnects 341 extending in parallel in the X direction, to supply VSS to the sources of the fin FETs. The M1 interconnects 341 are connected to the power line 7 formed in the M2 interconnect layer through vias.

Local interconnects 332 extending in the Y direction are connected in common to terminals of the fins 21 that are to be the drains of the fin FETs. The local interconnects 332 are connected to M1 interconnects 342 extending in parallel in the X direction through vias. The M1 interconnects 342 are connected to the M2 interconnect 51 through vias.

The configuration of the p-type output transistor section 104 is similar to that of the n-type output transistor section 103. The p-type output transistor section 104 includes ten fins 23 extending in parallel in the X direction. Buried power rails 312 extending in the Y direction are placed on the left and right sides of the fins 23 in the figure. The buried power rails 312 supply VDDIO. Gate interconnects 24 extending in the Y direction are placed across the ten fins 23. Fin FETs are formed by the fins 23 and the gate interconnects 24.

Local interconnects 335 extending in the Y direction are formed above the buried power rails 312 to overlap the buried power rails 312 in planar view. The local interconnects 335 are connected to the underlying buried power rails 312 through vias.

Local interconnects 333 extending in the Y direction are connected in common to terminals of the fins 23 that are to be the sources of the fin FETs. The local interconnects 333 are connected to the local interconnects 335 through five M1 interconnects 343 extending in parallel in the X direction, to supply VDDIO to the sources of the fin FETs. The M1 interconnects 343 are connected to the power line 6 formed in the M2 interconnect layer through vias.

Local interconnects 334 extending in the Y direction are connected in common to terminals of the fins 23 that are to be the drains of the fin FETs. Like the local interconnects 332, the local interconnects 334 are connected to the five M1 interconnects 342 extending in parallel in the X direction through vias.

According to the configuration described above, as the power lines supplying VSS, the buried power rails 311 are formed in the buried interconnect layer, the local interconnects 330 are formed, the power lines 341 are formed in the M1 interconnect layer, and the power line 7 is formed in the M2 interconnect layer. Since this decreases the resistance value in the VSS supply route, the power line 7 can be thinned. Also, as the power lines supplying VDDIO, the buried power rails 312 are formed in the buried interconnect layer, the local interconnects 335 are formed, the power lines 343 are formed in the M1 interconnect layer, and the power line 6 is formed in the M2 interconnect layer. Since this decreases the resistance value in the VDDIO supply route, the power line 6 can be thinned. It is therefore possible to thicken the output interconnect 51 in the M2 interconnect layer while preventing increase in the area of the output circuit. A large current can therefore be passed to the output terminal.

In addition, the buried power rail 311 supplying VSS and the buried power rail 312 supplying VDDIO are formed between the transistor N1 and the transistor P1 in planar view. Since buried power rails are formed by burying metal lines in grooves provided on the substrate, wells in the substrate, STIs, and the like, they have an advantage of reducing propagation of noise through the substrate and the like. Therefore, by providing the buried power rails 311 and 312 between the transistors N1 and P1, latch-up resistance can be improved.

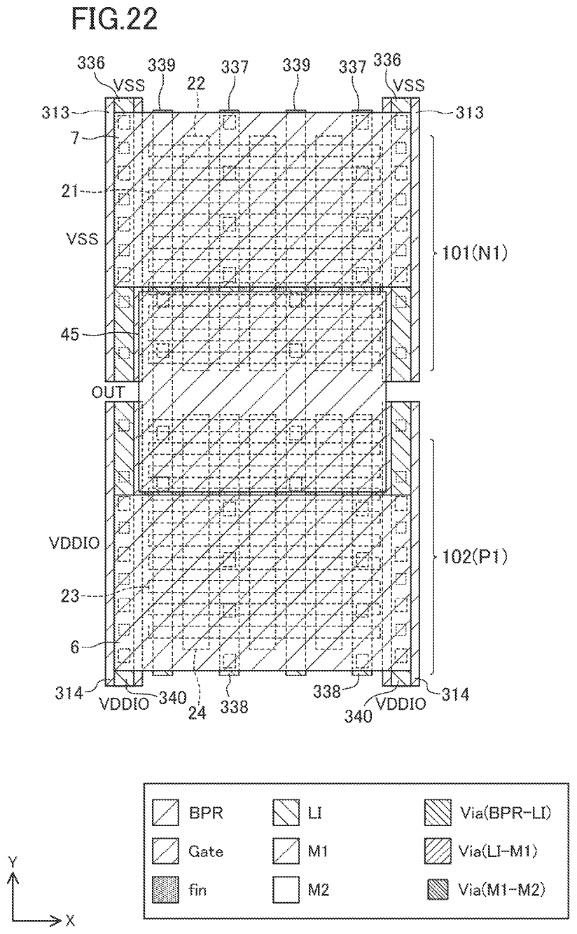

FIG. 22 is a plan view showing a layout of the output transistor sections of the IO cell 10A shown in FIG. 2A in this configuration example. FIG. 22 is a view corresponding to FIG. 8 shown in the first embodiment, and therefore description may be omitted here for configurations that can be easily guessed by analogy from the description in the first embodiment.

In FIG. 22, the upper part of the figure corresponds to the n-type output transistor section 101 constituting the transistor N1, and the lower part thereof corresponds to the p-type output transistor section 102 constituting the transistor P1. Fin FETs are formed in the n-type output transistor section 101 and the p-type output transistor section 102. Also, the power lines 6 and 7 shown in FIG. 2A are formed in the M1 interconnect layer. The power line 7 supplying VSS is provided above the n-type output transistor section 101, and the power line 6 supplying VDDIO is provided above the p-type output transistor section 102.

The n-type output transistor section 101 includes ten fins 21 extending in parallel in the X direction. Buried power rails 313 extending in the Y direction are formed on the left and right sides of the fins 21 in the figure. The buried power rails 313 supply VSS. Gate interconnects 22 extending in the Y direction are placed across the ten fins 21. Fin FETs are formed by the fins 21 and the gate interconnects 22.

Local interconnects 336 extending in the Y direction are formed above the buried power rails 313 to overlap the buried power rails 313 in planar view. The local interconnects 336 are connected to the underlying buried power rails 313 through vias. Also the local interconnects 336 are connected to the power line 7 formed above in the M1 interconnect layer through vias.

Local interconnects 337 extending in the Y direction are connected in common to terminals of the fins 21 that are to be the sources of the fin FETs. The local interconnects 337 are connected to the power line 7 formed in the M1 interconnect layer through vias, to supply VSS to the sources of the fin FETs.

The p-type output transistor section 102 includes ten fins 23 extending in parallel in the X direction. Buried power rails 314 extending in the Y direction are formed on the left and right sides of the fins 23 in the figure. The buried power rails 314 supply VDDIO. Gate interconnects 24 extending in the Y direction are placed across the ten fins 23. Fin FETs are formed by the fins 23 and the gate interconnects 24.

Local interconnects 340 extending in the Y direction are formed above the buried power rails 314 to overlap the buried power rails 314 in planar view. The local interconnects 340 are connected to the underlying buried power rails 314 through vias. Also the local interconnects 340 are connected to the power line 6 formed above in the M1 interconnect layer through vias.

Local interconnects 338 extending in the Y direction are connected in common to terminals of the fins 23 that are to be the sources of the fin FETs. The local interconnects 338 are connected to the power line 6 formed in the M1 interconnect layer through vias, to supply VDDIO to the sources of the fin FETs.

Local interconnects 339 extending in the Y direction are connected in common to terminals of the fins 21 that are to be the drains of the fin FETs in the n-type output transistor section 101 and to terminals of the fins 23 that are to be the drains of the fin FETs in the p-type output transistor section 102. The local interconnects 339 are connected to an M1 interconnect 45 formed in the M1 interconnect layer through vias. The M1 interconnect 45 is connected to an upper-layer pad electrode not shown.

According to the configuration described above, as the power lines supplying VSS, the buried power rails 313 are formed in the buried interconnect layer, the local interconnects 336 and 337 are formed, and the power line 7 is formed in the M1 interconnect layer. Since this decreases the resistance value in the VSS supply route, the power line 7 can be thinned. Also, as the power lines supplying VDDIO, the buried power rails 314 are formed in the buried interconnect layer, the local interconnects 338 and 340 are formed, and the power line 6 is formed in the M1 interconnect layer. Since this decreases the resistance value in the VDDIO supply route, the power line 6 can be thinned. It is therefore possible to thicken the output interconnect 45 in the M1 interconnect layer while preventing increase in the area of the output circuit. A large current can therefore be passed to the output terminal.

### Configuration Example 2

Configuration Example 2 corresponds to the alteration of the first embodiment. The circuit configuration of the output circuit is as shown in the circuit diagram of FIG. 9.

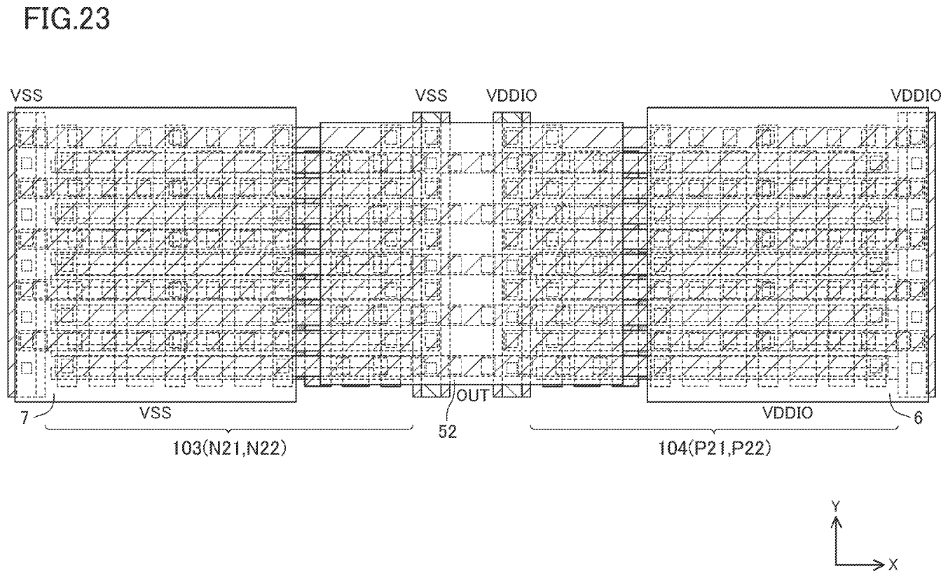

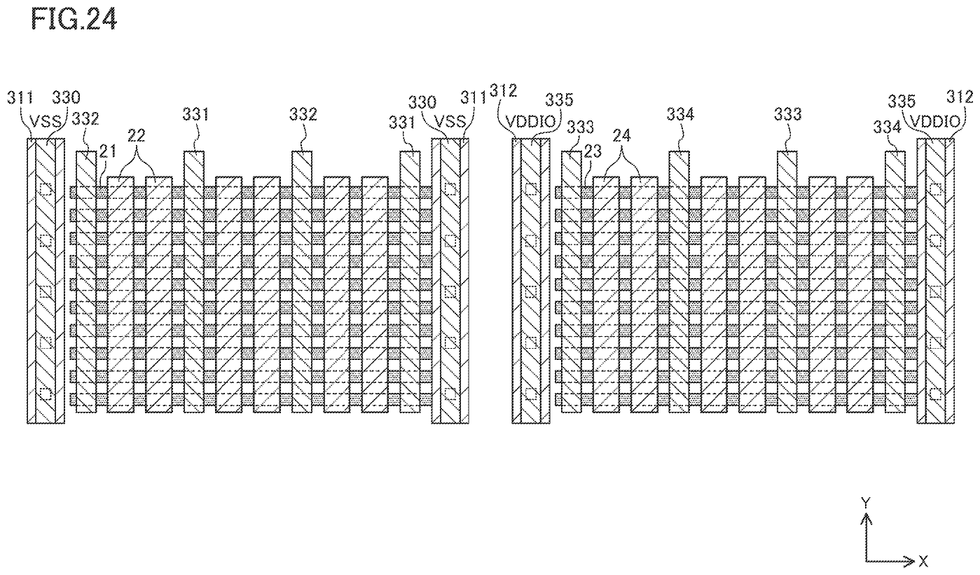

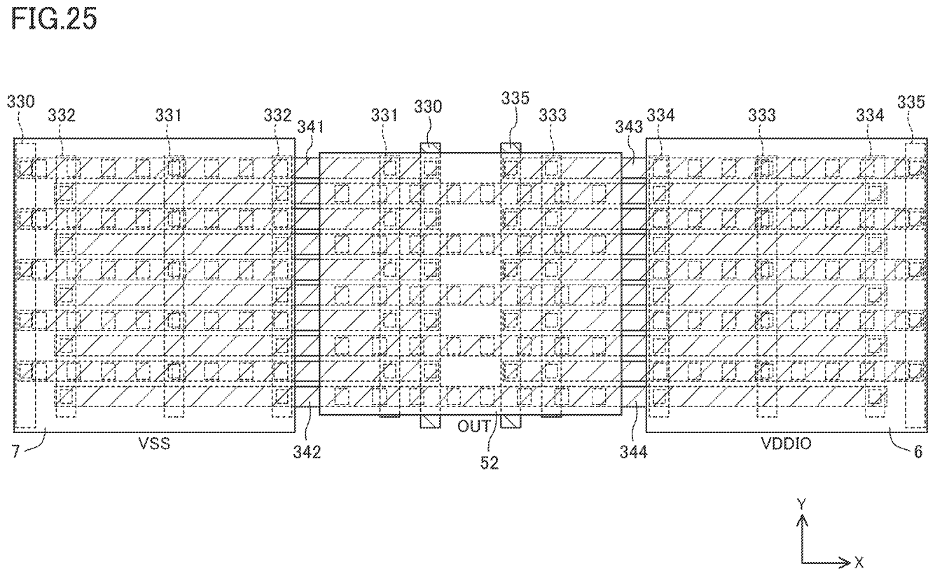

FIG. 23 is a plan view showing a layout of the output transistor sections of the IO cell 10B shown in FIG. 2B in this configuration example. FIGS. 24 and 25 are plan views showing the layout of FIG. 23 on a layer-by-layer basis, in which FIG. 24 shows a configuration of local interconnects and the lower portion below them and FIG. 25 shows a configuration of the local interconnects and the upper portion above them. FIGS. 23 to 25 are views corresponding to FIG. 10 shown in the alteration of the first embodiment, and therefore description may be omitted here for configurations that can be easily guessed by analogy from the description in the alteration of the first embodiment.

In FIGS. 23 to 25, the left part of the figure corresponds to the n-type output transistor section 103 constituting the transistors N21 and N22, and the right part thereof corresponds to the p-type output transistor section 104 constituting the transistors P21 and P22. Fin FETs are formed in the n-type output transistor section 103 and the p-type output transistor section 104. Also, the power lines 6 and 7 shown in FIG. 2B are formed in an M2 interconnect layer. The power line 7 supplying VSS is provided above the n-type output transistor section 103, and the power line 6 supplying VDDIO is provided above the p-type output transistor section 104. An output interconnect 52 is formed in the M2 interconnect layer. The M2 interconnect 52 is connected to an upper-layer pad electrode not shown.

In the layout of FIGS. 23 to 25, in comparison with the layout of FIGS. 19 to 21, the fins are longer because transistors are in two-stage serial connection, and two gate interconnects are placed between adjacent local interconnects. The basic configuration is however similar to that of Configuration Example 1 described above, and therefore detailed description thereof is omitted here.

In the layout of FIGS. 23 to 25, it is possible to thicken the output interconnect 52 in the M2 interconnect layer while preventing increase in the area of the output circuit. A large current can therefore be passed to the output terminal.

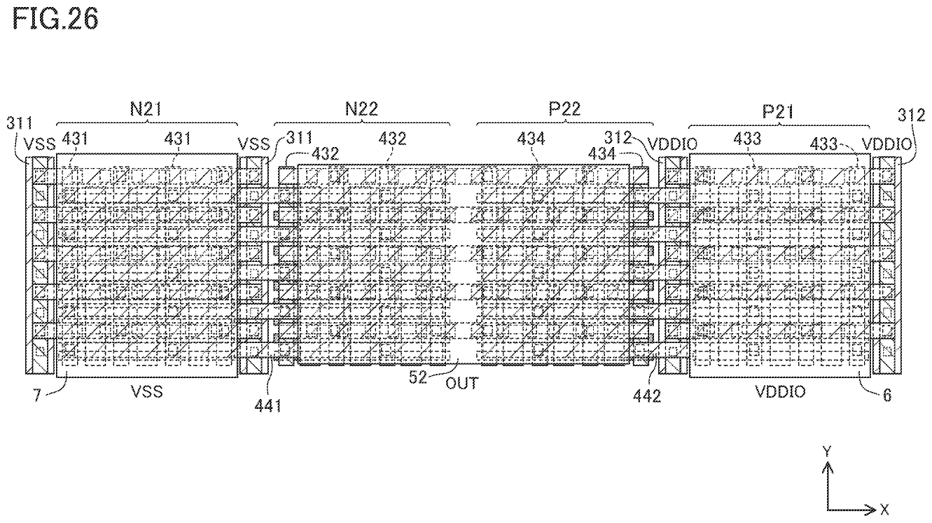

FIG. 26 shows an alteration of the configuration of FIG. 23. In the configuration of FIG. 23, the serially connected transistors N21 and N22 are constituted by the same continuous fins, and the serially connected transistors P21 and P22 are constituted by the same continuous fins. By contrast, in the configuration of FIG. 26, the fins constituting the transistor N21 and the fins constituting the transistor N22 are separated from each other, and the fins constituting the transistor P21 and the fins constituting the transistor P22 are separated from each other. That is, the transistor N21 and the transistor N22 are formed independently from each other: the structures constituting channels, gates, sources, and drains are separated from each other. Also, the transistor P21 and the transistor P22 are formed independently from each other: the structures constituting channels, gates, sources, and drains are separated from each other.

In the configuration of FIG. 26, a buried power rail 311 is formed between the transistor N21 and the transistor N22. Local interconnects 431 connected to terminals of the fins constituting the transistor N21 that are to be the drains of transistors and local interconnects 432 connected to terminals of the fins constituting the transistor N22 that are to be the sources of transistors are mutually connected through M1 interconnects 441 extending in the X direction.

Also, a buried power rail 312 is formed between the transistor P21 and the transistor P22. Local interconnects 433 connected to terminals of the fins constituting the transistor P21 that are to be the drains of transistors and local interconnects 434 connected to terminals of the fins constituting the transistor P22 that are to be the sources of transistors are mutually connected through M1 interconnects 442 extending in the X direction.

According to this alteration, the transistors N21 and N22 are formed by mutually separated fins, and the transistors P21 and P22 are formed by mutually separated fins. With this, the ESD tolerance of the semiconductor integrated circuit device can be improved.

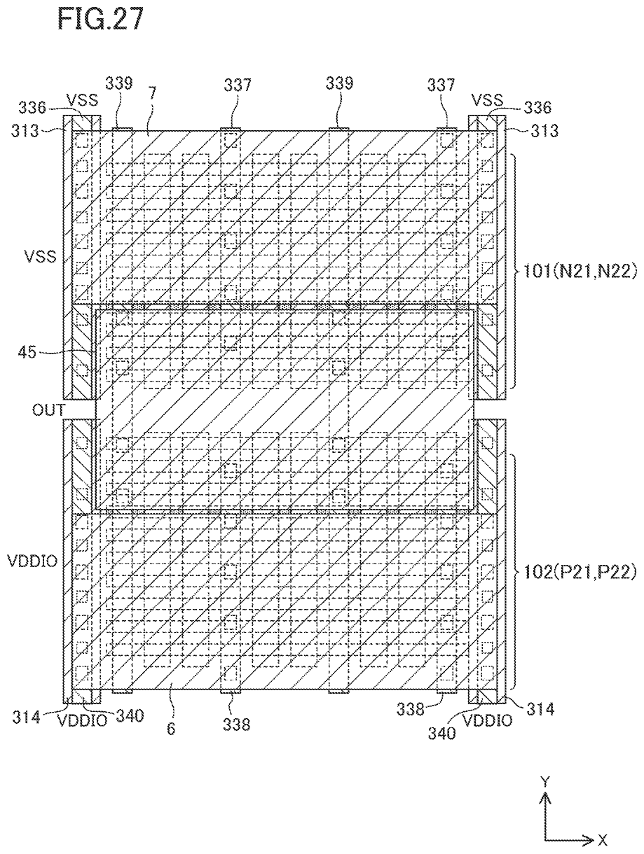

FIG. 27 is a plan view showing a layout of the output transistor sections of the IO cell 10A shown in FIG. 2A in this configuration example. FIG. 27 is a view corresponding to FIG. 11 shown in the alteration of the first embodiment, and therefore description may be omitted here for configurations that can be easily guessed by analogy from the description in the first embodiment.

In FIG. 27, the upper part of the figure corresponds to the n-type output transistor section 101 constituting the transistors N21 and N22, and the lower part thereof corresponds to the p-type output transistor section 102 constituting the transistors P21 and P22. Fin FETs are formed in the n-type output transistor section 101 and the p-type output transistor section 102. Also, the power lines 6 and 7 shown in FIG. 2A are formed in an M1 interconnect layer. The power line 7 supplying VSS is provided above the n-type output transistor section 101, and the power line 6 supplying VDDIO is provided above the p-type output transistor section 102. An output interconnect 45 is formed in the M1 interconnect layer.

In the layout of FIG. 27, in comparison with the layout of FIG. 22, the fins are longer because transistors are in two-stage serial connection, and two gate interconnects are placed between adjacent local interconnects. The basic configuration is however similar to that described above in this embodiment, and therefore detailed description thereof is omitted here.

In the layout of FIG. 27, it is possible to thicken the output interconnect 45 in the M1 interconnect layer while preventing increase in the area of the output circuit. A large current can therefore be passed to the output terminal.

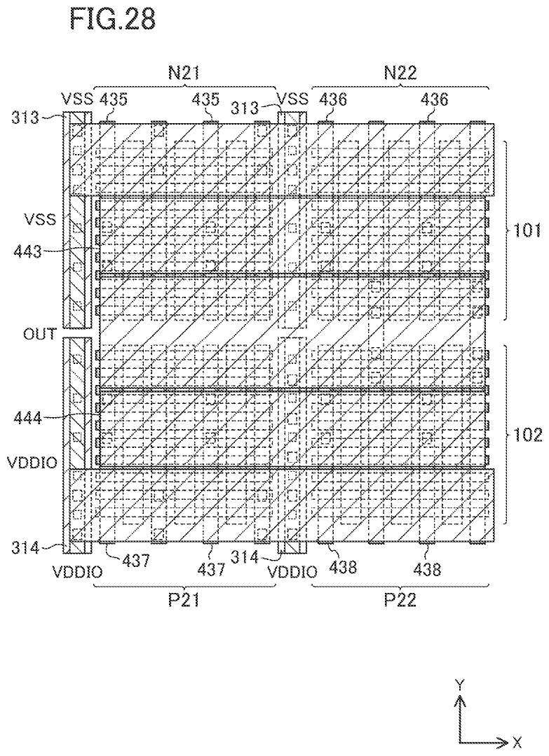

FIG. 28 shows an alteration of the configuration of FIG. 27. In the configuration of FIG. 27, the serially connected transistors N21 and N22 are constituted by the same continuous fins, and the serially connected transistors P21 and P22 are constituted by the same continuous fins. By contrast, in the configuration of FIG. 28, the fins constituting the transistor N21 and the fins constituting the transistor N22 are separated from each other, and the fins constituting the transistor P21 and the fins constituting the transistor P22 are separated from each other. That is, the transistor N21 and the transistor N22 are formed independently from each other: the structures constituting channels, gates, sources, and drains are separated from each other. Also, the transistor P21 and the transistor P22 are formed independently from each other: the structures constituting channels, gates, sources, and drains are separated from each other.

In the configuration of FIG. 28, a buried power rail 313 is formed between the transistor N21 and the transistor N22. Local interconnects 435 connected to terminals of the fins constituting the transistor N21 that are to be the drains of transistors and local interconnects 436 connected to terminals of the fins constituting the transistor N22 that are to be the sources of transistors are mutually connected through an M1 interconnect 443 extending in the X direction.

Also, a buried power rail 314 is formed between the transistor P21 and the transistor P22. Local interconnects 437 connected to terminals of the fins constituting the transistor P21 that are to be the drains of transistors and local interconnects 438 connected to terminals of the fins constituting the transistor P22 that are to be the sources of transistors are mutually connected through an M1 interconnect 444 extending in the X direction.

According to this alteration, the transistors N21 and N22 are formed by mutually separated fins, and the transistors P21 and P22 are formed by mutually separated fins. With this, the ESD tolerance of the semiconductor integrated circuit device can be improved.

### Configuration Example 3

Configuration Example 3 corresponds to the second embodiment described above. The entire configuration of the semiconductor integrated circuit device is as shown in FIG. 12, and the circuit configuration of the output circuit is as shown in the circuit diagram of FIG. 3.

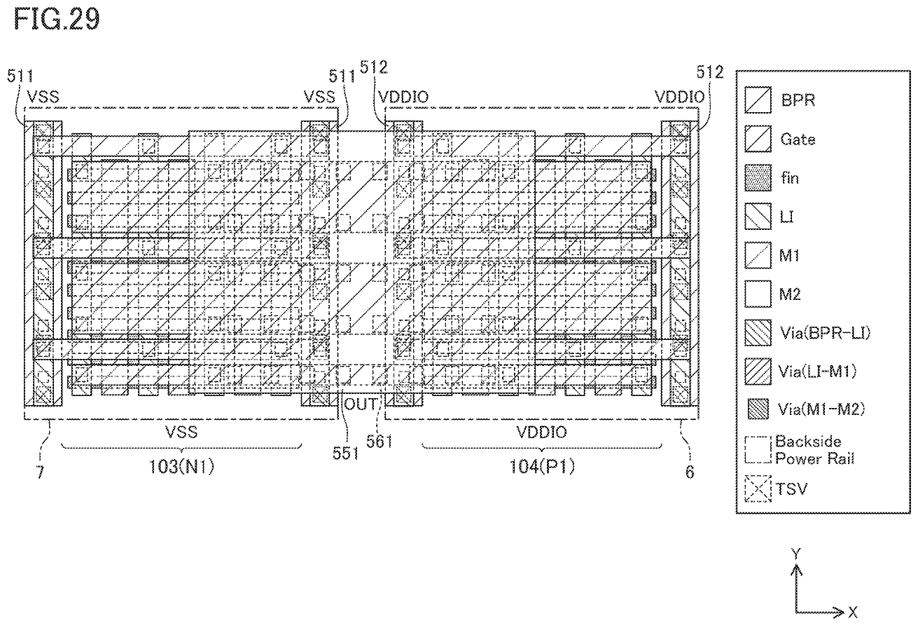

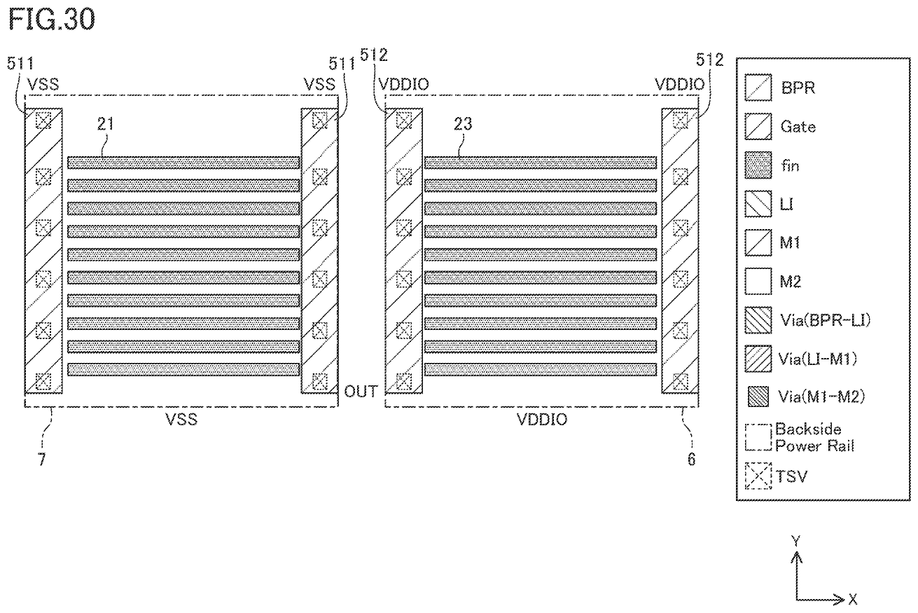

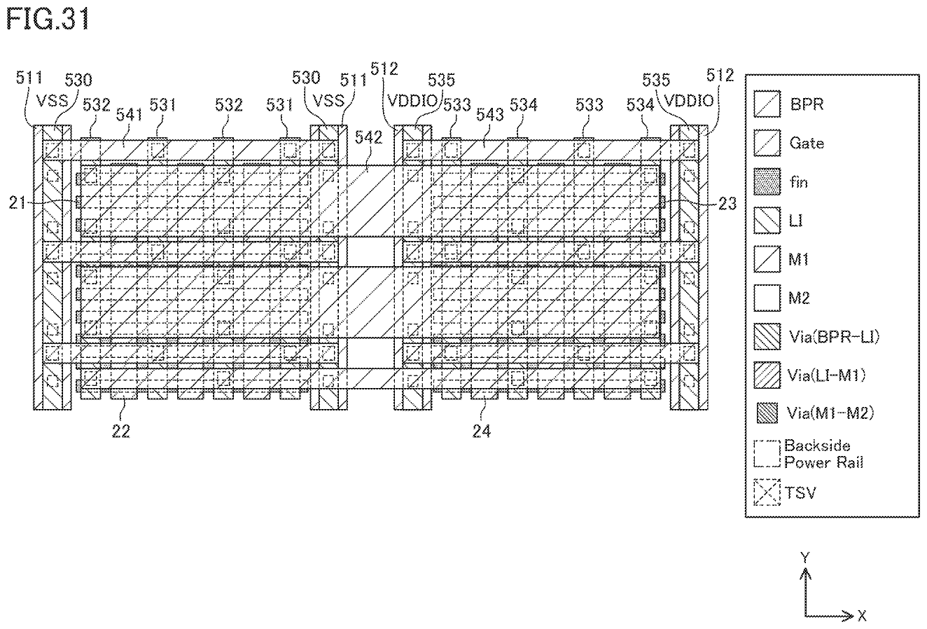

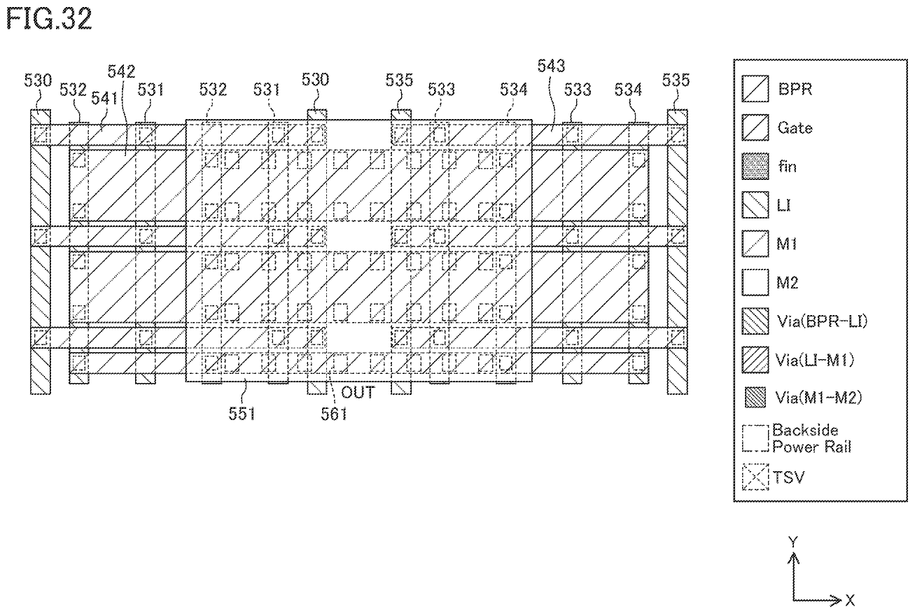

FIG. 29 is a plan view showing a layout of the output transistor sections of the IO cell 10B shown in FIG. 2B in Configuration Example 3. The layout of FIG. 29 corresponds to the circuit diagram of FIG. 3. FIGS. 30 to 32 are plan views showing the layout of FIG. 29 on a layer-by-layer basis, in which FIG. 30 shows a configuration of power lines in the second semiconductor chip 202 and buried power rails and fins in the first semiconductor chip 201, FIG. 31 shows a configuration of M1 interconnects and the lower portion below them in the first semiconductor chip 201, and FIG. 32 shows a configuration of local interconnects and the upper portion above them in the first semiconductor chip 201. FIGS. 29 to 32 are views corresponding to FIGS. 13 to 16 shown in the second embodiment, and therefore description may be omitted here for configurations that can be easily guessed by analogy from the description in the second embodiment.

In FIGS. 29 to 32, the left part of each figure corresponds to the n-type output transistor section 103 constituting the transistor N1, and the right part thereof corresponds to the p-type output transistor section 104 constituting the transistor P1. Fin FETs are formed in the n-type output transistor section 103 and the p-type output transistor section 104. Also, the power lines 6 and 7 shown in FIG. 2B are formed in the second semiconductor chip 202. The power line 7 supplying VSS is provided to overlap the n-type output transistor section 103 in planar view, and the power line 6 supplying VDDIO is provided to overlap the p-type output transistor section 104 in planar view.

The n-type output transistor section 103 includes ten fins 21 extending in parallel in the X direction. Buried power rails 511 extending in the Y direction are placed on the left and right sides of the fins 21 in the figure. The buried power rails 511 supply VSS. The buried power rails 511 are connected to the power line 7 in the second semiconductor chip 202 through TSVs. Gate interconnects 22 extending in the Y direction are placed across the ten fins 21. Fin FETs are formed by the fins 21 and the gate interconnects 22.

Local interconnects 530 extending in the Y direction are formed above the buried power rails 511 to overlap the buried power rails 511 in planar view. The local interconnects 530 are connected to the underlying buried power rails 511 through vias.

Local interconnects 531 extending in the Y direction are connected in common to terminals of the fins 21 that are to be the sources of the fin FETs. The local interconnects 531 are connected to the local interconnects 530 through M1 interconnects 541 extending in the X direction, to supply VSS to the sources of the fin FETs.

Local interconnects 532 extending in the Y direction are connected in common to terminals of the fins 21 that are to be the drains of the fin FETs. The local interconnects 532 are connected to M1 interconnects 542 extending in the X direction through vias. The M1 interconnects 542 are connected to an M2 interconnect 551 through vias. The M1 interconnects 542 and the M2 interconnect 551 correspond to output interconnects. The M2 interconnect 551 is connected to an upper-layer pad electrode not shown.

The p-type output transistor section 104 includes ten fins 23 extending in parallel in the X direction. Buried power rails 512 extending in the Y direction are placed on the left and right sides of the fins 23 in the figure. The buried power rails 512 supply VDDIO. The buried power rails 512 are connected to the power line 6 in the second semiconductor chip 202 through TSVs. Gate interconnects 24 extending in the Y direction are placed across the ten fins 23. Fin FETs are formed by the fins 23 and the gate interconnects 24.

Local interconnects 535 extending in the Y direction are formed above the buried power rails 512 to overlap the buried power rails 512 in planar view. The local interconnects 535 are connected to the underlying buried power rails 512 through vias.

Local interconnects 533 extending in the Y direction are connected in common to terminals of the fins 23 that are to be the sources of the fin FETs. The local interconnects 533 are connected to the local interconnects 535 through M1 interconnects 543 extending in the X direction, to supply VDDIO to the sources of the fin FETs.

Local interconnects 534 extending in the Y direction are connected in common to terminals of the fins 23 that are to be the drains of the fin FETs. The local interconnects 534 are connected to the M1 interconnects 542 extending in the X direction through vias.

The power lines 6 and 7 in the second semiconductor chip 202 have overlaps with the M2 interconnect 551 in the first semiconductor chip 201 in planar view. Also, the positions of vias 561 for connecting the M1 interconnects 542 and the M2 interconnect 551 overlap the power lines 6 and 7 in the second semiconductor chip 202 in planar view.

According to the configuration described above, as the power lines supplying VSS, provided are the buried power rails 511 formed in the buried interconnect layer of the first semiconductor chip 201 and the power line 7 formed in the second semiconductor chip 202. With this, the resistance value in the VSS supply route can be reduced even when the power lines in the M1 interconnect layer of the first semiconductor chip 201 are reduced. Also, as the power lines supplying VDDIO, provided are the buried power rails 512 formed in the buried interconnect layer of the first semiconductor chip 201 and the power line 6 formed in the second semiconductor chip 202. With this, the resistance value in the VDDIO supply route can be reduced even when the power lines in the M1 interconnect layer of the first semiconductor chip 201 are reduced. It is therefore possible to thicken the output interconnects 542 in the M1 interconnect layer and the output interconnect 551 in the M2 interconnect layer, and also increase the number of vias 561 for connecting these interconnects. A large current can therefore be passed to the output terminal. Moreover, the power lines 6 and 7 formed in the second semiconductor chip 202 can also be thickened as they have overlaps with the output interconnect 551 in planar view.

In addition, the buried power rail 511 supplying VSS and the buried power rail 512 supplying VDDIO are formed between the transistor N1 and the transistor P1 in planar view. Since buried power rails are formed by burying metal lines in grooves provided on the substrate, wells in the substrate, STIs, and the like, they have an advantage of reducing propagation of noise through the substrate and the like. Therefore, by providing buried power rails between the transistors N1 and P1, latch-up resistance can be improved.

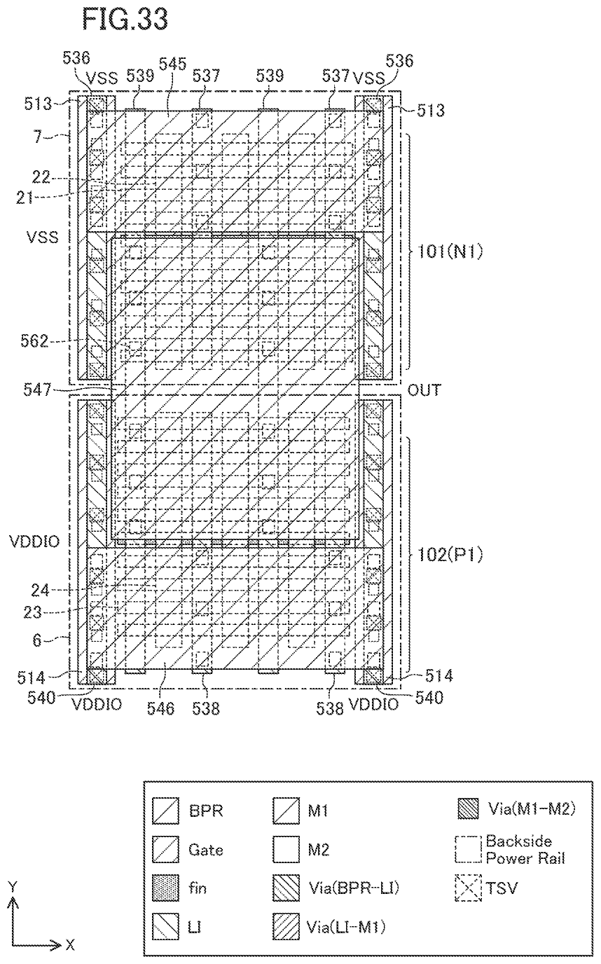

FIG. 33 is a plan view showing a layout of the output transistor sections of the IO cell 10A shown in FIG. 2A in Configuration Example 3. FIG. 33 corresponds to FIG. 18 shown in the second embodiment, and therefore description may be omitted here for configurations that can be easily guessed by analogy from the description in the second embodiment.

In FIG. 33, the upper part of the figure corresponds to the n-type output transistor section 101 constituting the transistor N1, and the lower part thereof corresponds to the p-type output transistor section 102 constituting the transistor P1. Fin FETs are formed in the n-type output transistor section 101 and the p-type output transistor section 102. Also, the power lines 6 and 7 shown in FIG. 2A are formed in the second semiconductor chip 202. The power line 7 supplying VSS is provided to overlap the n-type output transistor section 101 in planar view, and the power line 6 supplying VDDIO is provided to overlap the p-type output transistor section 102 in planar view.

The n-type output transistor section 101 includes ten fins 21 extending in parallel in the X direction. Buried power rails 513 extending in the Y direction are formed on the left and right sides of the fins 21 in the figure. The buried power rails 513 supply VSS. The buried power rails 513 are connected to the power line 7 in the second semiconductor chip 202 through TSVs. Gate interconnects 22 extending in the Y direction are placed across the ten fins 21. Fin FETs are formed by the fins 21 and the gate interconnects 22.

Local interconnects 536 extending in the Y direction are formed above the buried power rails 513 to overlap the buried power rails 513 in planar view. The local interconnects 536 are connected to the underlying buried power rails 513 through vias.

Local interconnects 537 extending in the Y direction are connected in common to terminals of the fins 21 that are to be the sources of the fin FETs. The local interconnects 537 are connected to the local interconnects 536 through an M1 interconnect 545 extending in the X direction, to supply VSS to the sources of the fin FETs.

The p-type output transistor section 102 includes ten fins 23 extending in parallel in the X direction. Buried power rails 514 extending in the Y direction are formed on the left and right sides of the fins 23 in the figure. The buried power rails 514 supply VDDIO. The buried power rails 514 are connected to the power line 6 in the second semiconductor chip 202 through TSVs. Gate interconnects 24 extending in the Y direction are placed across the ten fins 23. Fin FETs are formed by the fins 23 and the gate interconnects 24.

Local interconnects 540 extending in the Y direction are formed above the buried power rails 514 to overlap the buried power rails 514 in planar view. The local interconnects 540 are connected to the underlying buried power rails 514 through vias.

Local interconnects 538 extending in the Y direction are connected in common to terminals of the fins 23 that are to be the sources of the fin FETs. The local interconnects 538 are connected to the local interconnects 540 through an M1 interconnect 546 extending in the X direction, to supply VDDIO to the sources of the fin FETs.

Local interconnects 539 extending in the Y direction are connected in common to terminals of the fins 21 that are to be the drains of the fin FETs of the n-type output transistor section 101 and to terminals of the fins 23 that are to be the drains of the fin FETs of the p-type output transistor section 102. The local interconnects 539 are connected to an M1 interconnect 547 through vias 562. The local interconnects 539 and the M1 interconnect 547 correspond to output interconnects. The M1 interconnect 547 is connected to an upper-layer pad electrode not shown.

The power lines 6 and 7 in the second semiconductor chip 202 have overlaps with the M1 interconnect 547 in the first semiconductor chip 201 in planar view. Also, the positions of the vias 562 for connecting the local interconnects 539 and the M1 interconnect 547 overlap the power lines 6 and 7 in the second semiconductor chip 202 in planar view.

According to the configuration described above, as the power lines supplying VSS, provided are the buried power rails 513 formed in the buried interconnect layer of the first semiconductor chip 201 and the power line 7 formed in the second semiconductor chip 202. With this, the resistance value in the VSS supply route can be reduced even when no power line is provided in the M1 interconnect layer of the first semiconductor chip 201. Also, as the power lines supplying VDDIO, provided are the buried power rails 514 formed in the buried interconnect layer of the first semiconductor chip 201 and the power line 6 formed in the second semiconductor chip 202. With this, the resistance value in the VDDIO supply route can be reduced even when no power line is provided in the M1 interconnect layer of the first semiconductor chip 201. It is therefore possible to thicken the output interconnect 547 in the M1 interconnect layer, and also increase the number of vias 562 for connection with the local interconnects 539. A large current can therefore be passed to the output terminal. Moreover, the power lines 6 and 7 formed in the second semiconductor chip 202 can also be thickened as they have overlaps with the output interconnect 547 in planar view.

In the above embodiments, it was assumed to form fin FETs in the transistor sections. However, the transistors formed in the transistor sections are not limited to fin FETs, but may be nanosheet FETs, for example.

According to the present disclosure, it is possible to implement an output circuit capable of passing a large current through an output pad. The present disclosure is therefore useful for improving the performance of a semiconductor chip, for example.

1. An output circuit for outputting a signal from a semiconductor integrated circuit, comprising:
a first transistor of a first conductivity type connected between a first power supply supplying a first power supply voltage and an output terminal;
a first power line formed in a buried interconnect layer, the first power line extending in a first direction and supplying the first power supply voltage;
a second power line formed in a first interconnect layer located above the buried interconnect layer, the second power line extending in the first direction and supplying the first power supply voltage;
a third power line formed in a second interconnect layer located above the first interconnect layer, the third power line extending in a second direction perpendicular to the first direction and being connected to the second power line;
a first output interconnect formed in the first interconnect layer, the first output interconnect extending in the first direction and being connected to the output terminal; and
a second output interconnect formed in the second interconnect layer, the second output interconnect extending in the second direction and being connected to the first output interconnect.

2. The output circuit of claim 1, wherein
the second power line overlaps the first power line in planar view, and is connected to the first power line through a via.

3. The output circuit of claim 1, wherein
the first transistor includes a plurality of FETs arranged in the second direction,
the output circuit further comprises a first local interconnect formed in a local interconnect layer, the first local interconnect extending in the second direction and being connected in common to sources of the plurality of FETs, and
the first local interconnect is connected to the first power line and the second power line.

4. The output circuit of claim 1, wherein
the first transistor includes a plurality of FETs arranged in the first direction,
the output circuit further comprises a first local interconnect formed in a local interconnect layer, the first local interconnect extending in the first direction and being connected in common to sources of the plurality of FETs, and
the first local interconnect is connected to the first power line and the second power line.

5. The output circuit of claim 1, further comprising:
a second transistor of the first conductivity type connected in series with the first transistor between the first power supply and the output terminal,
wherein
structures of the first transistor and the second transistor, each constituting a channel, a gate, a source, and a drain, are separated from each other.

6. An output circuit for outputting a signal from a semiconductor integrated circuit, comprising:
a first transistor of a first conductivity type connected between a first power supply supplying a first power supply voltage and an output terminal;
a first power line formed in a buried interconnect layer, the first power line extending in a first direction and supplying the first power supply voltage;
a second power line formed in a first interconnect layer located above the buried interconnect layer, the second power line extending in a second direction perpendicular to the first direction and supplying the first power supply voltage;
a third power line formed in a second interconnect layer located above the first interconnect layer, the third power line extending in the first direction and being connected to the second power line;
a first output interconnect formed in the first interconnect layer, the first output interconnect extending in the second direction and being connected to the output terminal; and
a second output interconnect formed in the second interconnect layer, the second output interconnect extending in the first direction and being connected to the first output interconnect.

7. The output circuit of claim 6, wherein
the first transistor includes a plurality of FETs arranged in the second direction, and
the second power line is connected in common to sources of the plurality of FETs.

8. The output circuit of claim 6, further comprising:
a second transistor of a second conductivity type connected between a second power supply supplying a second power supply voltage and the output terminal,
wherein
the first power line is placed between the first transistor and the second transistor in planar view.

9. The output circuit of claim 6, wherein
the first transistor includes a plurality of FETs arranged in the first direction, and
the second power line is connected in common to sources of the plurality of FETs.

10. The output circuit of claim 6, further comprising:
a second transistor of the first conductivity type connected in series with the first transistor between the first power supply and the output terminal,
wherein
structures of the first transistor and the second transistor, each constituting a channel, a gate, a source, and a drain, are separated from each other.

11. An output circuit configured in a semiconductor integrated circuit device including a stack of a first semiconductor chip and a second semiconductor chip, a back face of the first semiconductor chip being opposed to a principal face of the second semiconductor chip, the output circuit comprising in the first semiconductor chip:
a first transistor of a first conductivity type connected between a first power supply supplying a first power supply voltage and an output terminal;
a first power line formed in a buried interconnect layer, the first power line extending in a first direction and supplying the first power supply voltage;
a first output interconnect formed in a first interconnect layer located above the buried interconnect layer, the first output interconnect extending in the first direction and being connected to the output terminal; and
a second output interconnect formed in a second interconnect layer located above the first interconnect layer, the second output interconnect extending in a second direction perpendicular to the first direction and being connected to the first output interconnect,
the output circuit further comprising in the second semiconductor chip:
a second power line extending in the second direction and having an overlap with the second output interconnect in planar view,
wherein
the second power line is connected to the first power line through a via formed on the back face of the first semiconductor chip.

12. The output circuit of claim 11, wherein
the second output interconnect has an overlap with the first output interconnect in planar view, and is connected to the first output interconnect through a first via, and
the position of the first via overlaps the second power line in planar view.

13. An output circuit configured in a semiconductor integrated circuit device including a stack of a first semiconductor chip and a second semiconductor chip, a back face of the first semiconductor chip being opposed to a principal face of the second semiconductor chip, the output circuit comprising in the first semiconductor chip:
a first transistor of a first conductivity type connected between a first power supply supplying a first power supply voltage and an output terminal;
a first power line formed in a buried interconnect layer, the first power line extending in a first direction and supplying the first power supply voltage;
a first output interconnect formed in a first interconnect layer located above the buried interconnect layer, the first output interconnect extending in a second direction perpendicular to the first direction and being connected to the output terminal; and
a second output interconnect formed in a second interconnect layer located above the first interconnect layer, the second output interconnect extending in the first direction and being connected to the first output interconnect,
the output circuit further comprising in the second semiconductor chip:
a second power line extending in the first direction and having an overlap with the second output interconnect in planar view,
wherein
the second power line is connected to the first power line through a via formed on the back face of the first semiconductor chip.

14. The output circuit of claim 13, wherein
the second output interconnect has an overlap with the first output interconnect in planar view, and is connected to the first output interconnect through a first via, and
the position of the first via overlaps the second power line in planar view.

15. The output circuit of claim 13, further comprising:
a second transistor of a second conductivity type connected between a second power supply supplying a second power supply voltage and the output terminal,
wherein
the first power line is placed between the first transistor and the second transistor in planar view.
